(19) United States
(12) Patent Application Publication
(10) Pub. No.: US 2026/0271495 A1
(43) Pub. Date: Sep. 10, 2026

(54) METHOD FOR MANUFACTURING LIGHT-EMITTING ELEMENT, LIGHT-EMITTING ELEMENT, AND DISPLAY DEVICE

(71) Applicant: Sharp Display Technology Corporation, Kameyama City, Mie (JP)

(72) Inventors: Sentaro KIDA, Sakai City, Osaka (JP); YASUSHI ASAOKA, Sakai City, Osaka (JP); Takahiro ADACHI, Sakai City, Osaka (JP); Yukio TAKENAKA, Sakai City, Osaka (JP)

(21) Appl. No.: 19/121,261

(22) PCT Filed: Oct. 19, 2022
(86) PCT No.: PCT/JP2022/038891

§ 371 Date: Apr. 15, 2025

(51) Int. Cl. H10K 50/115; H10K 71/15; H10K 71/20

(52) U.S. Cl. CPC H10K 50/115; H10K 71/15; H10K 71/233

(57) ABSTRACT

A method for manufacturing a light-emitting element includes preparing an underlayer substrate, forming a first resist pattern on the underlayer substrate The first resist pattern includes a first resist portion made of a material having resistance to a specific solvent and a first opening. The method includes applying a first solution onto the first resist pattern. The first solution includes a plurality of luminescent first quantum dots, the specific solvent, and a precursor of metal sulfide. The method includes removing the first resist portion to leave at least a portion of a first metal sulfide film formed by the application of the first solution as a first light-emitting layer.

### TECHNICAL FIELD

The disclosure relates to a method for manufacturing a light-emitting element, a light-emitting element, and a display device.

### BACKGROUND ART

In the related art, a method for manufacturing a light-emitting element is known in which light-emitting layers including quantum dots (QDs) are separately patterned by a lift-off method (PTL 1).

### CITATION LIST

### Patent Literature

PTL 1: JP 2009-87760 A

### SUMMARY

### Technical Problem

The present inventors have paid a particular attention to an inorganic QD layer including QDs and an inorganic matrix that includes and holds the QDs. The “inorganic matrix” refers to a member that is made of an inorganic material and that includes and holds other substances. That is, the inorganic matrix herein refers to a member that is made of an inorganic material and that includes and holds QDs. This inorganic matrix is an element constituting a film in which the QDs are distributed.

An object of an aspect of the disclosure is to separately pattern inorganic QD layers including QDs and an inorganic matrix by a lift-off method.

### Solution to Problem

In order to achieve the object described above, a method for manufacturing a light-emitting element according to an aspect of the disclosure includes preparing an underlayer substrate, forming a first resist pattern on the underlayer substrate, the first resist pattern including a first resist portion and a first opening, the first resist portion being made of a material having resistance to a specific solvent, applying a first solution onto the first resist pattern, the first solution including a plurality of first quantum dots, the specific solvent, and a precursor of an inorganic medium, and the plurality of first quantum dots being luminescent, removing the first resist portion to leave at least a portion of a first inorganic medium film as a first light-emitting layer, the first inorganic medium being formed by the application of the first solution, and exposing a coating film of the first solution, subsequent to the application of the first solution and in advance of the removal of the first resist portion, to cause an exposed portion to become the first inorganic medium layer including the plurality of first quantum dots.

In order to achieve the object described above, a light-emitting element according to an aspect of the disclosure includes a lower electrode, a bank covering an edge of the lower electrode, a first inorganic medium layer not overlapping the bank in a plan view and including a continuous film of an inorganic medium including a plurality of quantum dots, and a second inorganic medium layer overlapping the bank in a plan view, including a plurality of quantum dots, and having a concentration of the inorganic medium lower than a concentration of the first inorganic medium layer.

In order to achieve the object described above, a display device according to an aspect of the disclosure includes the light-emitting element according to the aspect of the disclosure.

### Advantageous Effects of Disclosure

According to an aspect of the disclosure, inorganic QD layers including QDs and an inorganic matrix can be separately patterned by a lift-off method.

### BRIEF DESCRIPTION OF DRAWINGS

FIG. 1 is a cross-sectional view illustrating a lower layer forming step of a method for manufacturing a light-emitting element according to a first embodiment.

FIG. 2 is a cross-sectional view illustrating a first color template forming step of the method for manufacturing the light-emitting element.

FIG. 3 is a cross-sectional view illustrating a first color application step of the method for manufacturing the light-emitting element.

FIG. 4 is a cross-sectional view illustrating an exposure step of the method for manufacturing the light-emitting element.

FIG. 5 is a cross-sectional view illustrating a peeling step of the method for manufacturing the light-emitting element.

FIG. 6 is a cross-sectional view illustrating a second color template forming step of the method for manufacturing the light-emitting element.

FIG. 7 is a cross-sectional view illustrating a second color application step the method for manufacturing the light-emitting element.

FIG. 8 is a cross-sectional view illustrating a second color exposure step of the method for manufacturing the light-emitting element.

FIG. 9 is a cross-sectional view illustrating a second color peeling step of the method for manufacturing the light-emitting element.

FIG. 10 is a cross-sectional view illustrating a third color template forming step of the method for manufacturing the light-emitting element.

FIG. 11 is a cross-sectional view illustrating a third color application step of the method for manufacturing the light-emitting element.

FIG. 12 is a cross-sectional view illustrating a third color exposure step of the method for manufacturing the light-emitting element.

FIG. 13 is a cross-sectional view illustrating a third color peeling step of the method for manufacturing the light-emitting element.

FIG. 14 is a cross-sectional view illustrating a CTL forming step of the method for manufacturing the light-emitting element.

FIG. 15 is a cross-sectional view illustrating a lower layer forming step of a modified example of the method for manufacturing the light-emitting element according to the first embodiment.

FIG. 16 is a cross-sectional view illustrating a first color template forming step of the modified example of the manufacturing method.

FIG. 17 is a cross-sectional view illustrating a first color application step of the modified example of the manufacturing method.

FIG. 18 is a cross-sectional view illustrating an exposure step of the modified example of the manufacturing method.

FIG. 19 is a cross-sectional view illustrating a peeling step of the modified example of the manufacturing method.

FIG. 20 is a cross-sectional view illustrating a second color template forming step of the modified example of the manufacturing method.

FIG. 21 is a cross-sectional view illustrating a second color application step of the modified example of the manufacturing method.

FIG. 22 is a cross-sectional view illustrating a second color exposure step of the modified example of the manufacturing method.

FIG. 23 is a cross-sectional view illustrating a second color peeling step of the modified example of the manufacturing method.

FIG. 24 is a cross-sectional view illustrating a third color template forming step of the modified example of the manufacturing method.

FIG. 25 is a cross-sectional view illustrating a third color application step of the modified example of the manufacturing method.

FIG. 26 is a cross-sectional view illustrating a third color exposure step of the modified example of the manufacturing method.

FIG. 27 is a cross-sectional view illustrating a third color peeling step of the modified example of the manufacturing method.

FIG. 28 is a cross-sectional view illustrating a CTL forming step of the modified example of the manufacturing method.

FIG. 29 is a cross-sectional view of a light-emitting element according to a second embodiment.

FIG. 30 is a cross-sectional view of a light-emitting element according to a comparative example.

FIG. 31 is a cross-sectional view illustrating a first exposure step of a method for manufacturing a light-emitting element according to the second embodiment.

FIG. 32 is a cross-sectional view illustrating a second exposure step of the method for manufacturing the light-emitting element.

FIG. 33 is a cross-sectional view illustrating a third exposure step of the method for manufacturing the light-emitting element.

FIG. 34 is a cross-sectional view illustrating a peeling step of the method for manufacturing the light-emitting element.

FIG. 35 is a cross-sectional view illustrating a CTL forming step of the method for manufacturing the light-emitting element.

FIG. 36 is a cross-sectional view illustrating a lower layer forming step of a method for manufacturing a light-emitting element according to a third embodiment.

FIG. 37 is a cross-sectional view illustrating a first color template forming step of the method for manufacturing the light-emitting element.

FIG. 38 is a cross-sectional view illustrating a liquid repellency imparting step of the method for manufacturing the light-emitting element.

FIG. 39 is a cross-sectional view illustrating a first color application step according to a post application method of the method for manufacturing the light-emitting element.

FIG. 40 is a cross-sectional view illustrating an exposure/peeling step according to the post application method of the method for manufacturing the light-emitting element.

FIG. 41 is a cross-sectional view illustrating a liquid repellency imparting step according to a transfer method of the method for manufacturing the light-emitting element.

FIG. 42 is a cross-sectional view illustrating a first color application step according to the transfer method of the method for manufacturing the light-emitting element.

FIG. 43 is a cross-sectional view illustrating an exposure/peeling step according to the transfer method of the method for manufacturing the light-emitting element.

FIG. 44 is a cross-sectional view illustrating a liquid repellency imparting step according to a liquid-repellent agent mixing resist method of the method for manufacturing the light-emitting element.

FIG. 45 is a cross-sectional view illustrating a first color application step according to the liquid-repellent agent mixing resist method of the method for manufacturing the light-emitting element.

FIG. 46 is a cross-sectional view illustrating an exposure/peeling step according to the liquid-repellent agent mixing resist method of the method for manufacturing the light-emitting element.

FIG. 47 is a cross-sectional view illustrating a liquid repellency imparting step according to a liquid-repellent portion layering method of the method for manufacturing the light-emitting element.

FIG. 48 is a cross-sectional view illustrating a first color application step according to the liquid-repellent portion layering method of the method for manufacturing the light-emitting element.

FIG. 49 is a cross-sectional view illustrating an exposure/peeling step according to the liquid-repellent portion layering method of the method for manufacturing the light-emitting element.

FIG. 50 is a cross-sectional view of a light-emitting element according to a fourth embodiment.

FIG. 51 is a cross-sectional view of a modified example of the light-emitting element according to the fourth embodiment.

FIG. 52 is a cross-sectional view of another modified example of the light-emitting element according to the fourth embodiment.

FIG. 53 is a cross-sectional view of yet another modified example of the light-emitting element according to the fourth embodiment.

FIG. 54 is a cross-sectional view illustrating a first color application step of a method for manufacturing a light-emitting element according to a fifth embodiment.

FIG. 55 is a cross-sectional view illustrating an upper layer CTL application step of the method for manufacturing the light-emitting element.

FIG. 56 is a cross-sectional view illustrating an exposure step of the method for manufacturing the light-emitting element.

FIG. 57 is a cross-sectional view illustrating a peeling step of the method for manufacturing the light-emitting element.

FIG. 58 is a cross-sectional view of a light-emitting element according to a sixth embodiment.

FIG. 59 is a plan view of a light-emitting element according to a seventh embodiment.

FIG. 60 is a plan view of a modified example of the light-emitting element.

FIG. 61 is a plan view of another modified example of the light-emitting element.

FIG. 62 is a plan view of yet another modified example of the light-emitting element.

FIG. 63 is a plan view illustrating a first color forming step of a method for manufacturing a light-emitting element according to the seventh embodiment.

FIG. 64 is a plan view illustrating a second color forming step of the method for manufacturing the light-emitting element.

FIG. 65 is a plan view illustrating a third color forming step of the method for manufacturing the light-emitting element.

FIG. 66 is a plan view illustrating a light-emitting element manufactured by the method for manufacturing the light-emitting element.

FIG. 67 is a plan view illustrating a first color forming step of another method for manufacturing a light-emitting element according to the seventh embodiment.

FIG. 68 is a plan view illustrating a second color forming step of the other method for manufacturing the light-emitting element.

FIG. 69 is a plan view illustrating a third color forming step of the other method for manufacturing the light-emitting element.

FIG. 70 is a plan view of yet another modified example of the light-emitting element according to the seventh embodiment.

### DESCRIPTION OF EMBODIMENTS

### First Embodiment

When attempting to separately pattern inorganic QD layers including an inorganic matrix by a lift-off method, a polar solvent for application of the inorganic QD layers dissolves positive-type resist patterns for forming the inorganic QD layers. Therefore, in a first embodiment, by using solvent-resistant resist patterns, the resist patterns are not dissolved in the polar solvent, and the inorganic QD layers can be separately patterned by the lift-off method.

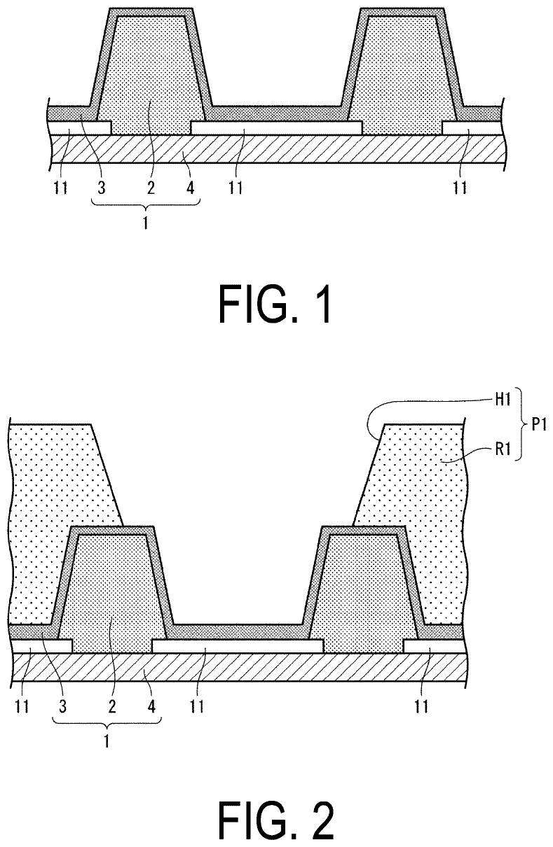

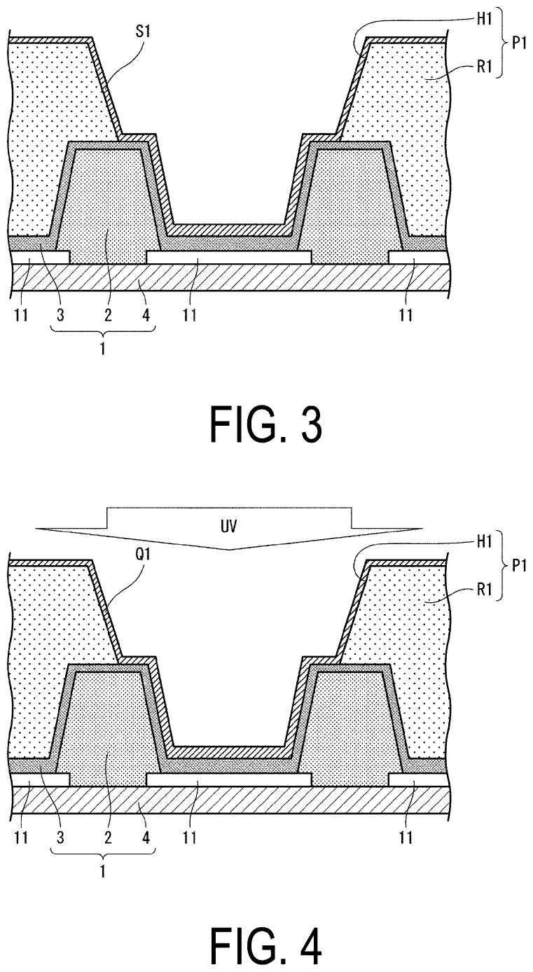

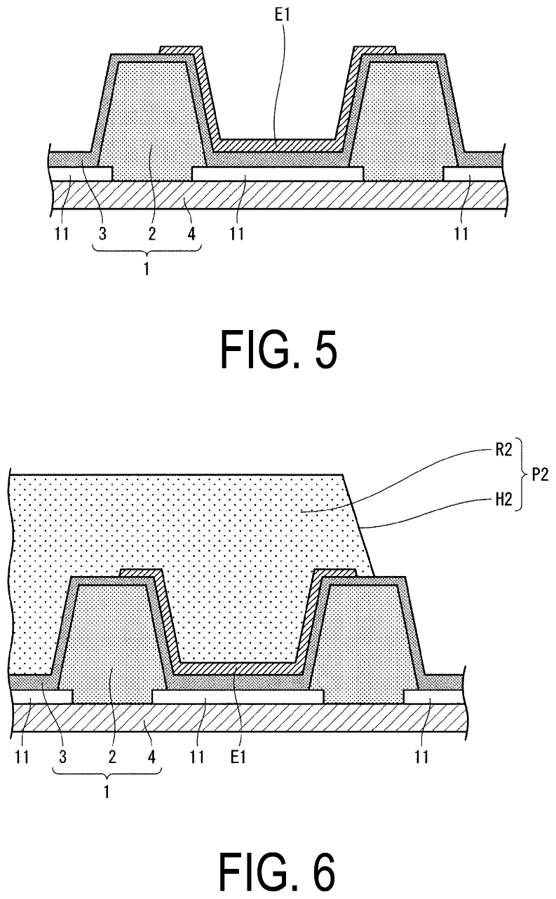

FIG. 1 is a cross-sectional view illustrating a lower layer forming step of a method for manufacturing a light-emitting element according to the first embodiment. FIG. 2 is a cross-sectional view illustrating a first color template forming step of the method for manufacturing the light-emitting element. FIG. 3 is a cross-sectional view illustrating a first color application step. FIG. 4 is a cross-sectional view illustrating an exposure step. FIG. 5 is a cross-sectional view illustrating a peeling step.

First, as illustrated in FIG. 1, an underlayer substrate 1 is prepared that includes a substrate 4, a bank 2 formed on the substrate 4, and a lower function layer 3 that is formed so as to cover the substrate 4 and the bank 2.

Then, as illustrated in FIG. 2, a first resist pattern P1, including a first resist portion R1 made of a material resistant to a polar solvent and a first opening H1, is formed on the underlayer substrate 1. In FIG. 2, the first opening H1 has a forwardly tapered shape in which the upper side is wider than the substrate 4 side, but the first opening H1 may have a reversely tapered shape in which the upper side is narrowed. When the first resist pattern P1 is a positive-type in which solubility with respect to a developing solution increases when light is applied, the first resist pattern P1 is formed by exposing and developing a first color pixel portion, and when the first resist pattern P1 is a negative-type in which the solubility with respect to the developing solution decreases when light is applied, the first resist pattern P1 is formed by exposing and developing a portion other than the first color pixel portion. When the first resist pattern Pl is made of, for example, a water-soluble material, the first resist pattern P1 is generally resistant to polar solvents. Examples of the water-soluble material include polyvinyl pyrrolidone (PVP), polyvinyl alcohol (PVA), polyacrylic acid, polyacrylamide, polyethylene oxide, polyvinyl amide, polyamine, copolymers of two or more kinds thereof, and derivatives thereof. The copolymers include, for example, PVA-PVP grafted copolymers. Hereinafter, a case in which the first resist pattern P1 is of the positive-type will be described.

Subsequently, as illustrated in FIG. 3, a first solution S1 including a plurality of first quantum dots that are luminescent, a polar solvent, and a precursor of an inorganic matrix is applied to the entire surface including the first resist pattern P1 and a region from which the surface of the lower function layer 3 is exposed. When the inorganic matrix is a metal sulfide, the precursor of the inorganic matrix preferably includes metal sulfide. The precursor of the metal sulfide inorganic matrix preferably includes zinc dithiocarboxylate. The first resist portion R1 preferably includes a PVA-PVP grafted copolymer. Examples of the polar solvent of the first solution S1 include tetrahydrofuran (THF), methylformamide (NMF), N,N-dimethylformamide (DMF), diethyl sulfide, and the like.

Thereafter, as illustrated in FIG. 4, after evaporating the polar solvent from the coating film of the first solution S1 on the entire surface including the first resist pattern P1 and the region from which the surface of the lower function layer 3 is exposed, the entire surface is exposed to ultraviolet rays (UV) or infrared rays in order to react zinc dithiocarboxylate included in the coating film to obtain a zinc sulfide, and to cause the exposed portion to become a first metal sulfide film Q1 including the plurality of first quantum dots. The first metal sulfide film Q1 is preferably a continuous film having an area of 1000 nm² or more in a plane direction intersecting the thickness direction of the underlayer substrate 1.

Note that baking may be performed instead of the exposure.

Then, as illustrated in FIG. 5, the first resist portion R1 of the first resist pattern P1 is removed so as to leave a part of the first metal sulfide film Q1 as a first light-emitting layer E1. By removing the first resist portion R1, of the first metal sulfide film Q1, a portion located on the first resist portion R1 is removed so as to leave a remaining portion as the first light-emitting layer E1. The first resist portion R1 is preferably removed by a stripper to which a surfactant is added.

The first resist portion R1 is removed by peeling the first metal sulfide film Q1 from the underlayer substrate 1 using a stripper. As the stripper, water, dimethyl sulfoxide (DMSO), or N-methyl-2-pyrrolidone (NMP) is used. In order to facilitate the peeling of the first resist portion R1 and the first metal sulfide film Q1 from the underlayer substrate 1, a surfactant may be added to the stripper, or an external force such as ultrasonic waves (US) or shower peeling may be applied.

The underlayer substrate 1 includes the bank 2. Then, as illustrated in FIG. 5, a part of the first light-emitting layer E1 is located above the bank 2.

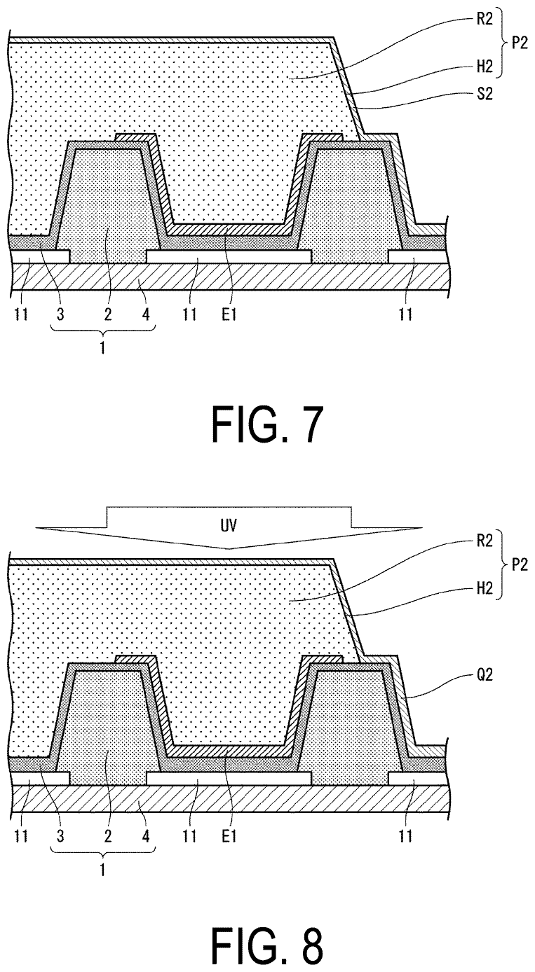

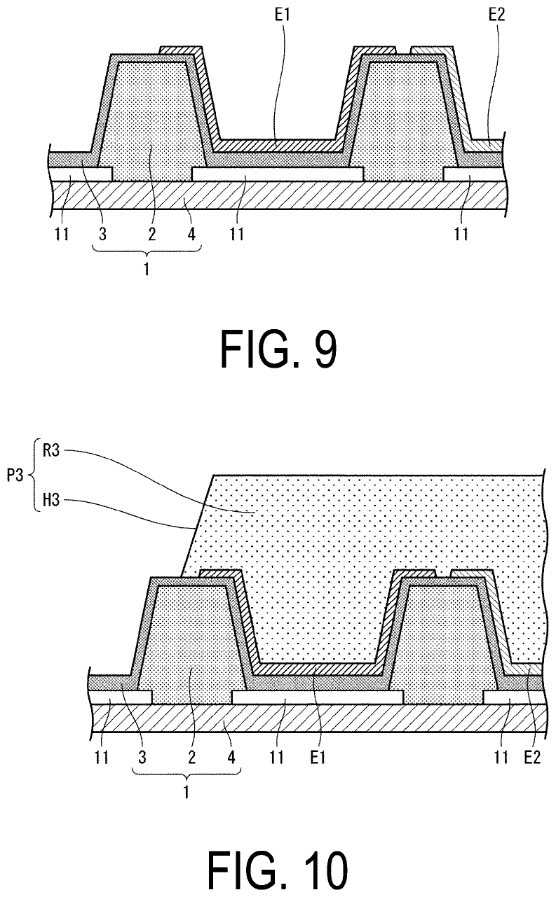

FIG. 6 is a cross-sectional view illustrating a second color template forming step of the method for manufacturing the light-emitting element. FIG. 7 is a cross-sectional view illustrating a second color application step. FIG. 8 is a cross-sectional view illustrating a second color exposure step. FIG. 9 is a cross-sectional view illustrating a second color peeling step. Constituent elements similar to the constituent elements described above are denoted by the same reference signs and numerals, and detailed descriptions thereof will not be repeated.

Subsequently, as illustrated in FIG. 6, after forming the first light-emitting layer E1, a second resist pattern P2, including a second resist portion R2 made of a material having resistance to the polar solvent, and a second opening H2, is formed. The second opening H2 includes a region in which the first light-emitting layer E1 is not formed.

Thereafter, as illustrated in FIG. 7, a second solution S2 including a plurality of second quantum dots that are luminescent, the polar solvent, and the precursor of the inorganic matrix is applied to the entire surface on the second resist pattern P2 and the lower function layer 3. The first quantum dot and the second quantum dot may be configured to emit different colors.

Then, as illustrated in FIG. 8, the coating film of the second solvent S2 on the entire surface on the second resist pattern P2 and the lower function layer 3 is exposed in order to react zinc dithiocarboxylate and cause the exposed portion to become a second metal sulfide film Q2 including the plurality of second quantum dots.

Subsequently, as illustrated in FIG. 9, the second resist portion R2 of the second resist pattern P2 is removed so as to leave at least a part of the second metal sulfide film Q2 as a second light-emitting layer E2.

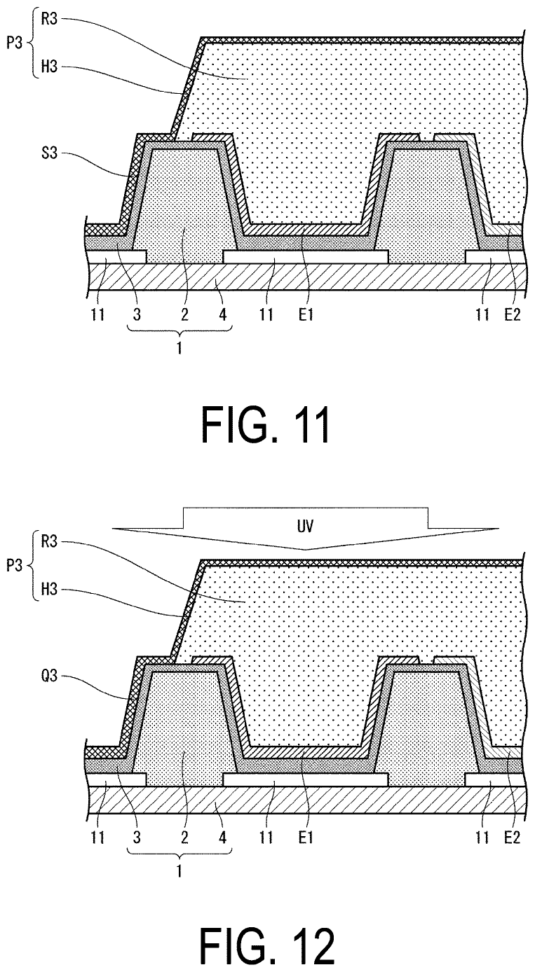

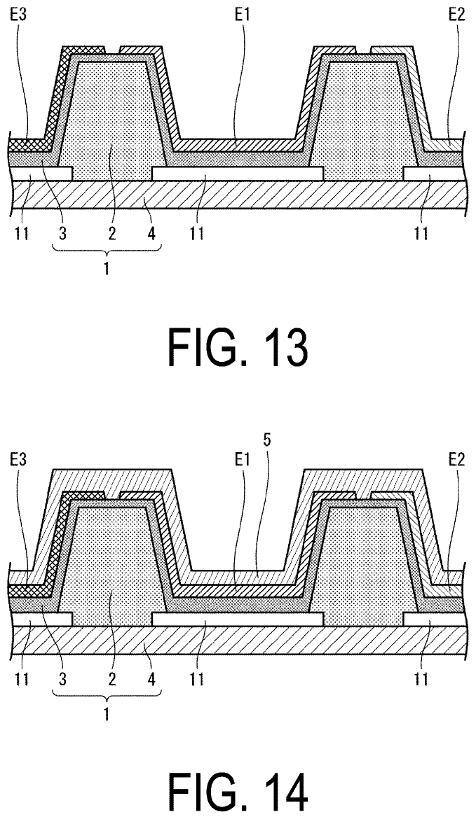

FIG. 10 is a cross-sectional view illustrating a third color template forming step of the method for manufacturing the light-emitting element. FIG. 11 is a cross-sectional view illustrating a third color application step. FIG. 12 is a cross-sectional view illustrating a third color exposure step. FIG. 13 is a cross-sectional view illustrating a third color peeling step. FIG. 14 is a cross-sectional view illustrating a CTL forming step. Constituent elements similar to the constituent elements described above are denoted by the same reference signs and numerals, and detailed descriptions thereof will not be repeated.

Then, as illustrated in FIG. 10, after forming the second light-emitting layer E2, a third resist pattern P3, including a third resist portion R3 made of a material having resistance to the polar solvent, and a third opening H3, is formed. The third opening H3 includes a region in which the first light-emitting layer E1 and the second light-emitting layer E2 are not formed.

Subsequently, as illustrated in FIG. 11, a third solution S3 including a plurality of third quantum dots that are luminescent, the polar solvent, and the precursor of the inorganic matrix is applied to the entire surface on the third resist pattern P3 and the lower function layer 3.

Thereafter, as illustrated in FIG. 12, the coating film of the third solution S3 on the entire surface on the third resist pattern P3 and the lower function layer 3 is exposed in order to cause the exposed portion to become a third metal sulfide film Q3 including the plurality of third quantum dots.

Then, as illustrated in FIG. 13, the third resist portion R3 of the third resist pattern P3 is removed so as to leave at least a part of the third metal sulfide film Q3 as a third light-emitting layer E3.

Subsequently, as illustrated in FIG. 14, an upper function layer 5 is formed to be in contact with the first light-emitting layer E1, the second light-emitting layer E2, and the third light-emitting layer E3. In the case of a forward configuration in which the anode is closer to the substrate 4 than the cathode, the upper function layer 5 can be made of an inorganic material such as ZnO, MgZnO, LiZnO, AlZnO, or a mixture thereof, and in the case of a reverse configuration in which the cathode is closer to the substrate 4 than the anode, the upper function layer 5 can be made of an inorganic material such as NiO, MoO₃, or TiO₂, or an organic material such as TFB(poly(9,9-dioctylfluorene-co-N-(4-butylphenyl)-diphenylamine)), P-TPD(poly (9-vinylcarbazole)), or PVK(poly(9-vinylcarbazole)).

Thereafter, an upper electrode located above the first light-emitting layer E1, the second light-emitting layer E2, and the third light-emitting layer E3 is formed. The first light-emitting layer E1, the second light-emitting layer E2, and the third light-emitting layer E3 cause electroluminescence to occur in a visible light region by injection of electric charges into the quantum dots by a voltage applied between the underlayer substrate 1 and the upper electrode.

The first light-emitting layer E1 includes the plurality of first quantum dots that are luminescent, and the inorganic matrix that includes and holds the first quantum dots. The inorganic matrix includes metal sulfide. The metal sulfide includes zinc sulfide.

The inorganic matrix is desirably filled in the light-emitting layer. The inorganic matrix preferably fills a region other than the quantum dots in the light-emitting layer. The inorganic matrix preferably infills a region other than the quantum dots in the light-emitting layer. Note that the outer edge of the light-emitting layer need not necessarily be formed of only the inorganic matrix, and some of the quantum dots may be exposed from the inorganic matrix.

The inorganic matrix may be a portion of the light-emitting layer excluding the quantum dots. The inorganic matrix preferably includes the plurality of quantum dots. The inorganic matrix may be formed so as to fill spaces formed between the plurality of quantum dots. The inorganic matrix may partially or completely fill the spaces between the quantum dots.

The inorganic matrix desirably includes a continuous film having an area of 1000 nm² or more in a plane direction orthogonal to the film thickness direction. The continuous film means a region that is not separated by a material other than the material constituting the continuous film in one plane. In the continuous film of the inorganic matrix, it is desirable that an inorganic material constituting the inorganic matrix, which will be described later, continuously has an area of 1000 nm² or more in the plane direction orthogonal to the film thickness direction.

The same material as the shell material of the quantum dot may be used for the inorganic matrix. In that case, an average distance between cores adjacent to each other (core-to-core distance) is preferably 3 nm or greater, or may be 5 nm or greater.

Alternatively, the average distance between the cores adjacent to each other is preferably 0.5 times or more an average core diameter. The core-to-core distance is obtained by averaging the shortest distances between 20 adjacent cores in a cross-sectional observation. The core-to-core distance is preferably kept wider than the distance obtained when the shell materials are in contact with each other. The average core diameter is obtained by averaging the core diameters of 20 adjacent cores in a cross-sectional observation. The core diameter can be the diameter of a circle having the same area as the core area in a cross-sectional observation.

The concentration of the inorganic matrix in the light-emitting layer may be from 9% to 70% when measured from an area ratio in image processing in a cross-sectional observation. Further, when the quantum dot has a core/shell structure, the concentration of the shell may be from 0% to 58%. Further, when the shell material and the inorganic matrix material are the same (the constituent elements are the same), it is substantially difficult to distinguish between the shell and the inorganic matrix. Thus, it is sufficient that the concentration of a region including both the inorganic matrix and the shell be in a numerical range obtained by adding a numerical range of the concentration of the shell to a numerical range of the concentration of the inorganic matrix.

The inorganic matrix is preferably solid at room temperature. Unlike the core or the shell of the quantum dot, the inorganic matrix may have an amorphous structure.

The light-emitting layer may be made of the quantum dots and the inorganic matrix. The strength of the chain structure of carbon detected when the light-emitting layer is analyzed by the gas chromatography-mass spectrometry or the Fourier transform infrared spectroscopy may be equal to or less than the noise. When the light-emitting layer does not include organic ligands, the strength of the chain structure of carbon becomes as weak as the noise or less.

The inorganic material constituting the inorganic matrix desirably has a band gap wider than the band gap of the constituent material of the quantum dots. The inorganic material constituting the inorganic matrix may be a semiconductor material or an insulator material. The inorganic material constituting the inorganic matrix may be a sulfide semiconductor.

The inorganic material constituting the inorganic matrix includes, for example, a metal sulfide and/or a metal oxide. The metal sulfide may be, for example, zinc sulfide (ZnS), zinc magnesium sulfide (ZnMgS, ZnMgS₂), gallium sulfide (GaS, Ga₂S₃), zinc tellurium sulfide (ZnTeS), magnesium sulfide (MgS), zinc gallium sulfide (ZnGa₂S₄), or magnesium sulfide (MgGa₂S₄). The metal oxide may be zinc oxide (ZnO), titanium oxide (TiO₂), tin oxide (SnO₂), tungsten oxide (WO₃), zirconium oxide (ZrO₂), or silicon oxide (SiO₂). Note that the chemical formula written within parentheses after the compound name is a representative example. In addition, the composition ratio described in the chemical formula is desirably stoichiometry in which the actual composition of the compound is the same as the chemical formula, but needs not necessarily be stoichiometry.

Note that the above-described structure of the inorganic matrix need not necessarily be observed over the entire area of the light-emitting layer as long as the above-described structure is observed in a range of about 100 nm in a cross-sectional observation of the light-emitting layer.

Further, it is sufficient that the main material of the inorganic matrix be an inorganic material, and a material different from the main inorganic material may be added as an additive.

### Modified Example of First Embodiment

As described above, when attempting to separately pattern the inorganic QD layers including the inorganic matrix by the lift-off method, the polar solvent for the application of the inorganic QD layers dissolves the resist patterns for forming the inorganic QD layers. In a modified example of the first embodiment, by using a low-polarity solvent to which the resist patterns have resistance instead of the polar solvent, the resist patterns are not dissolved in the low-polarity solvent, and the inorganic QD layers can be separately patterned by the lift-off method.

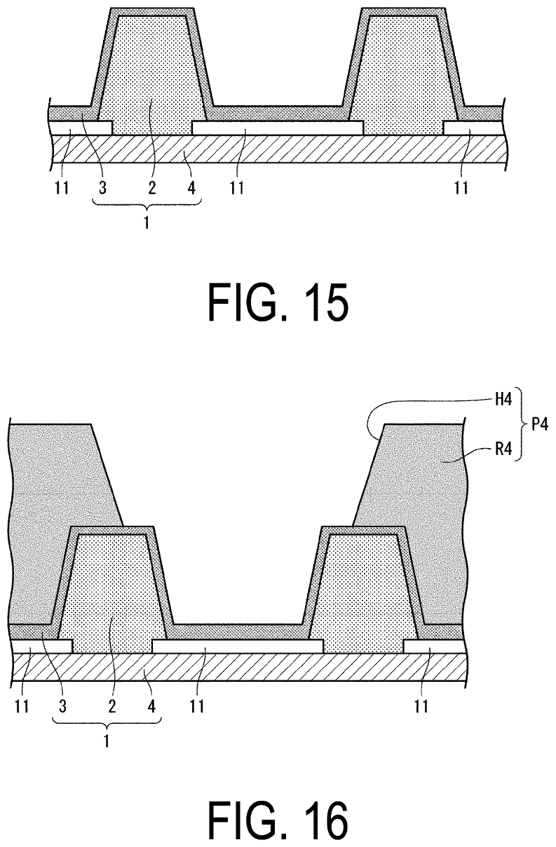

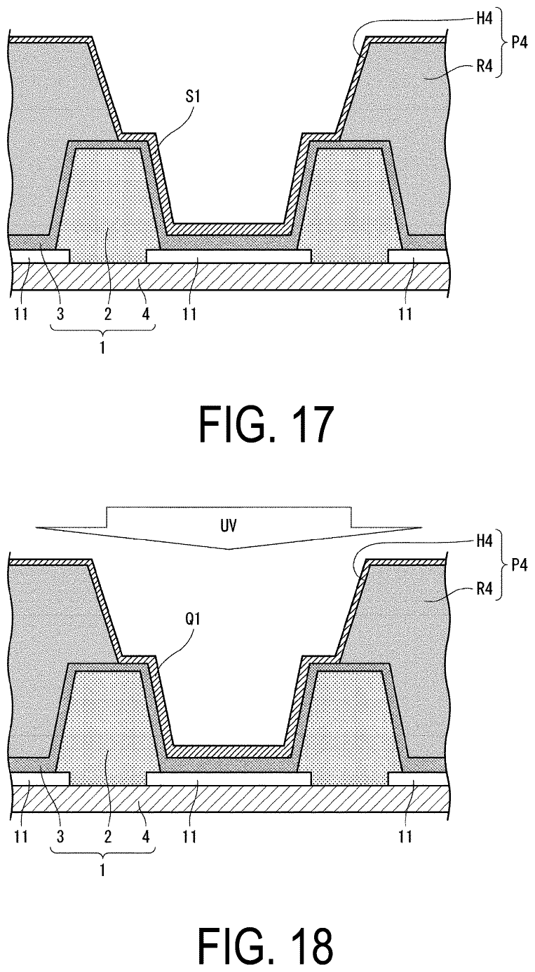

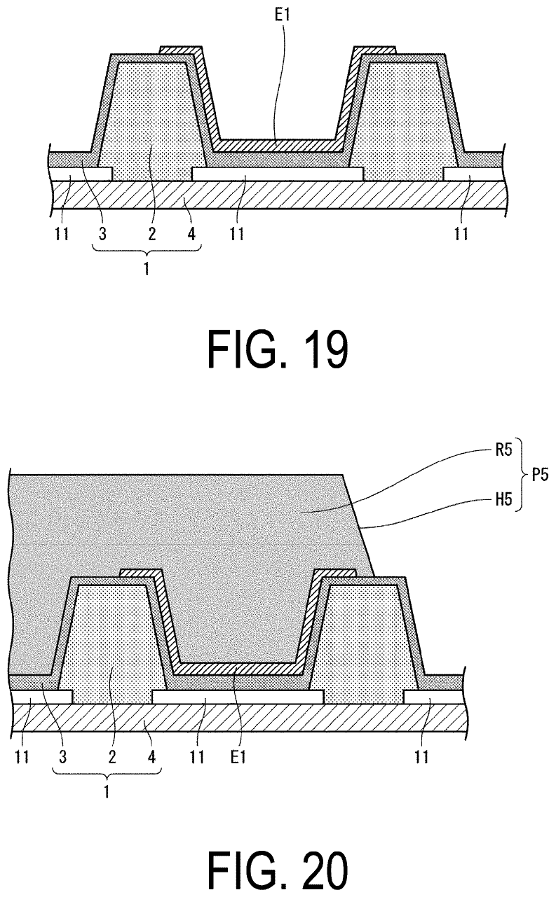

FIG. 15 is a cross-sectional view illustrating a lower layer forming step of the modified example of the method for manufacturing the light-emitting element according to the first embodiment. FIG. 16 is a cross-sectional view illustrating a first color template forming step of the modified example. FIG. 17 is a cross-sectional view illustrating a first color application step of the modified example. FIG. 18 is a cross-sectional view illustrating an exposure step of the modified example. FIG. 19 is a cross-sectional view illustrating a peeling step of the modified example. Constituent elements similar to the constituent elements described above are denoted by the same reference signs and numerals, and detailed descriptions thereof will not be repeated.

First, as illustrated in FIG. 15, the underlayer substrate 1 is prepared that includes the substrate 4, the bank 2 formed on the substrate 4, and the lower function layer 3 that is formed so as to cover the substrate 4 and the bank 2.

Then, as illustrated in FIG. 16, a first resist pattern P4, including a first resist portion R4 made of a material resistant to the low-polarity solvent, and a first opening H4, is formed on the underlayer substrate 1. When the first solution S1 is a polar solvent, if the resist pattern is made of a known general resist material, the first solution S1 causes the resist pattern to deteriorate. Here, the general resist material may be, for example, a material that includes photosensitive polyimide, a positive-type phenolic resin, or a negative-type acrylic resin. Thus, when the first solution S1 is changed from the polar solvent to the low-polarity solvent, the deterioration of the resist pattern can be suppressed even when the known general resist material is used. The first resist pattern P4 is the same as the known general resist material. As the low-polarity solvent used in the application step illustrated in FIG. 17 described later, a low-polarity solvent such as toluene, hexane, or chlorobenzene can be used, but toluene is preferably used.

The low-polarity solvent refers to a solvent in which the square root of the sum of squares of the dipole term and the hydrogen bond term in the Hansen solubility parameter is 8.3 or less.

Subsequently, as illustrated in FIG. 17, the first solution S1 including the plurality of first quantum dots that are luminescent, the low-polarity solvent, and the precursor of the inorganic matrix is applied to the entire surface on the first resist pattern P4 and the lower function layer 3.

Thereafter, as illustrated in FIG. 18, the coating film of the first solution S1 on the entire surface on the first resist pattern P4 and the lower function layer 3 is exposed in order to react zinc dithiocarboxylate, and to cause the exposed portion to become the first metal sulfide film Q1 including the plurality of first quantum dots.

Then, as illustrated in FIG. 19, the first resist portion R4 of the first resist pattern P4 is removed so as to leave at least a part of the first metal sulfide film Q1 as the first light-emitting layer E1.

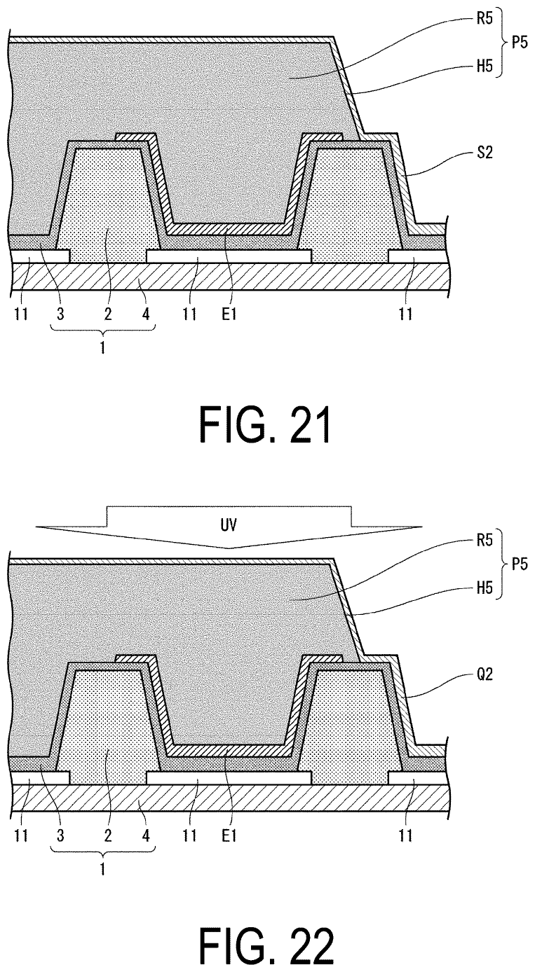

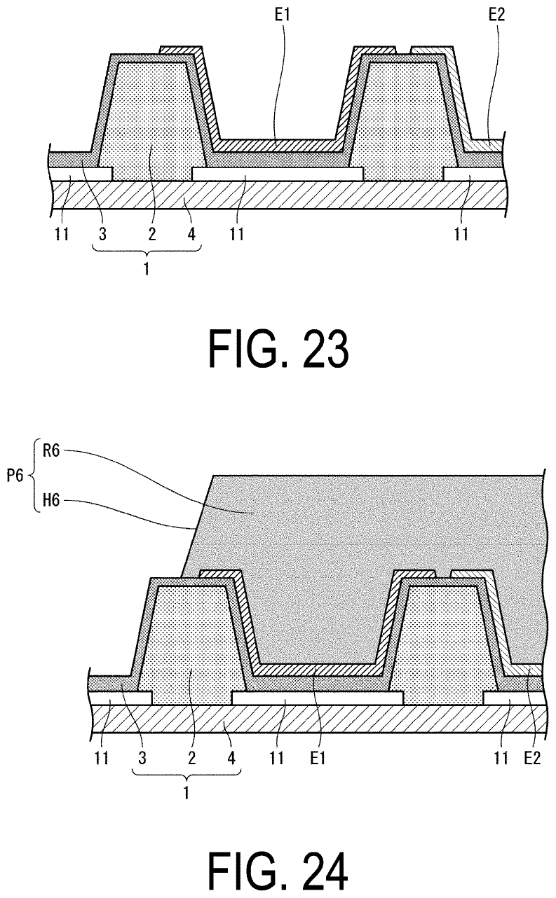

FIG. 20 is a cross-sectional view illustrating a second color template forming step of the modified example of the manufacturing method. FIG. 21 is a cross-sectional view illustrating a second color application step of the modified example. FIG. 22 is a cross-sectional view illustrating a second color exposure step of the modified example. FIG. 23 is a cross-sectional view illustrating a second color peeling step of the modified example. Constituent elements similar to the constituent elements described above are denoted by the same reference signs and numerals, and detailed descriptions thereof will not be repeated.

Subsequently, as illustrated in FIG. 20, after forming the first light-emitting layer E1, a second resist pattern P5, including a second resist portion R5 made of a material having resistance to the low-polarity solvent, and a second opening H5, is formed.

Thereafter, as illustrated in FIG. 21, the second solution S2 including the plurality of second quantum dots that are luminescent, the low-polarity solvent, and the precursor of the inorganic matrix is applied to the entire surface on the second resist pattern P5 and the lower function layer 3.

Then, as illustrated in FIG. 22, the coating film of the second solution S2 on the entire surface on the second resist pattern P5 and the lower function layer 3 is exposed in order to react zinc dithiocarboxylate, and to cause the exposed portion to become the second metal sulfide film Q2 including the plurality of second quantum dots.

Subsequently, as illustrated in FIG. 23, the second resist portion R5 of the second resist pattern P5 is removed so as to leave at least a part of the second metal sulfide film Q2 as the second light-emitting layer E2.

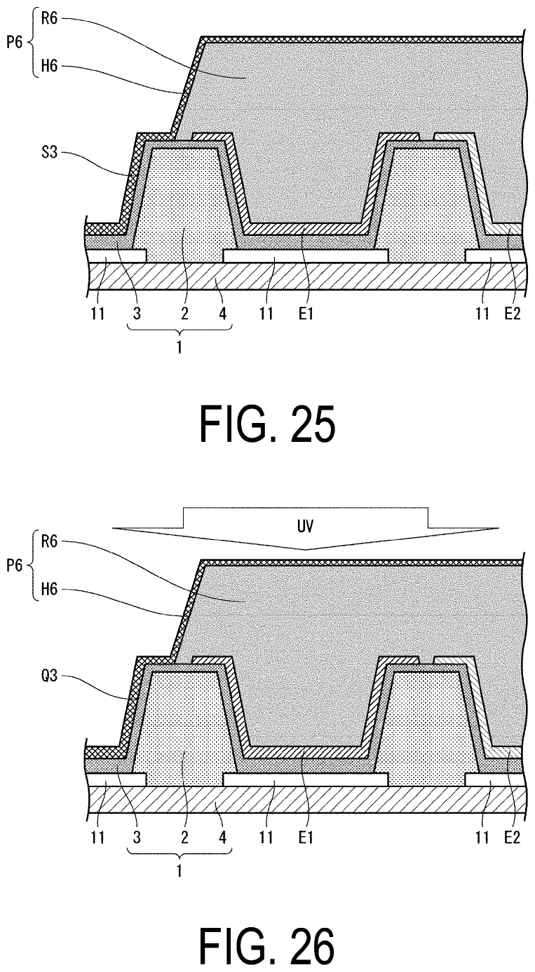

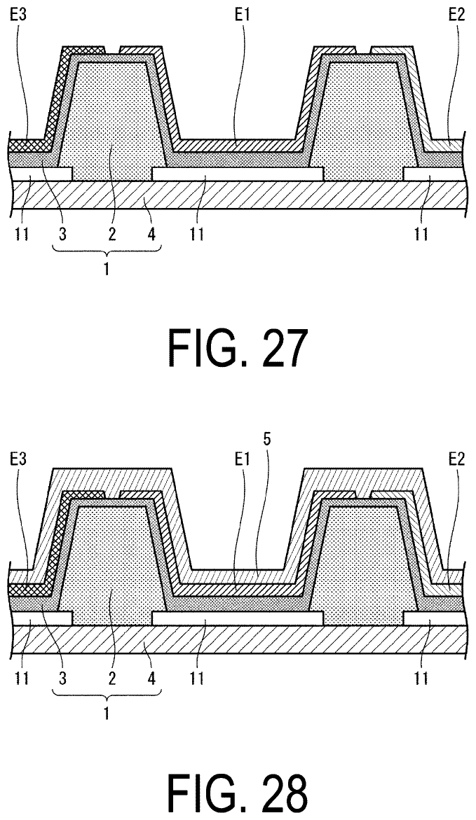

FIG. 24 is a cross-sectional view illustrating a third color template forming step of the modified example of the manufacturing method. FIG. 25 is a cross-sectional view illustrating a third color application step of the modified example. FIG. 26 is a cross-sectional view illustrating a third color exposure step of the modified example. FIG. 27 is a cross-sectional view illustrating a third color peeling step of the modified example. FIG. 28 is a cross-sectional view illustrating a CTL forming step of the modified example. Constituent elements similar to the constituent elements described above are denoted by the same reference signs and numerals, and detailed descriptions thereof will not be repeated.

Then, as illustrated in FIG. 24, after forming the second light-emitting layer E2, a third resist pattern P6 including a third resist portion R6 made of a material having resistance to the low-polarity solvent, and a third opening portion H6, is formed.

Subsequently, as illustrated in FIG. 25, the third solution S3 including the plurality of third quantum dots that are luminescent, the low-polarity solvent, and the precursor of the inorganic matrix is applied to the entire surface on the third resist pattern P6 and the lower function layer 3.

Thereafter, as illustrated in FIG. 26, the coating film of the third solution S3 on the entire surface on the third resist pattern P6 and the lower function layer 3 is exposed in order to cause the exposed portion to become the third metal sulfide film Q3 including the plurality of third quantum dots.

Then, as illustrated in FIG. 27, the third resist portion R6 of the third resist pattern P6 is removed so as to leave at least a part of the third metal sulfide film Q3 as the third light-emitting layer E3.

Subsequently, as illustrated in FIG. 28, the upper function layer 5 is formed to be in contact with the first light-emitting layer E1, the second light-emitting layer E2, and the third light-emitting layer E3.

### Second Embodiment

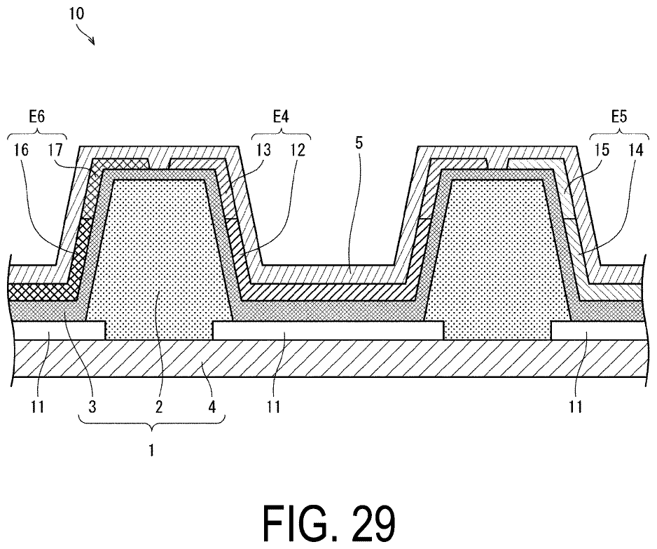

FIG. 29 is a cross-sectional view of a light-emitting element 10 according to a second embodiment. Constituent elements similar to the constituent elements described above are denoted by the same reference signs and numerals, and detailed descriptions thereof will not be repeated.

The light-emitting element 10 includes lower electrodes 11, the banks 2 covering the edges of the lower electrodes 11, light-emitting layers 12, 14, and 16 (first inorganic medium layers) each not overlapping the bank 2 in a plan view and including a continuous film of an inorganic medium including a plurality of quantum dots, and deactivation layers 13, 15, and 17 (second inorganic medium layers) each overlapping the bank 2 in a plan view, including a plurality of quantum dots, and having a lower concentration of the inorganic medium than the light-emitting layers 12, 14, and 16. The light-emitting layers 12, 14, and 16 are layers including the plurality of quantum dots that are luminescent and an inorganic matrix material, and the deactivation layers 13, 15, and 17 are layers including the plurality of quantum dots that are deactivated. The light-emitting layers 12, 14, and 16 are connected to the deactivation layers 13, 15, and 17, respectively. That is, the light-emitting layer 12 is connected to the deactivation layer 13. The light-emitting layer 14 is connected to the deactivation layer 15. The light-emitting layer 16 is connected to the deactivation layer 17.

The light-emitting layer 12 and the deactivation layer 13 constitute a first light-emitting layer E4. The light-emitting layer 14 and the deactivation layer 15 constitute a second light-emitting layer E5. The light-emitting layer 16 and the deactivation layer 17 constitute a third light-emitting layer E6.

Since the deactivation layers 13, 15, and 17 are unexposed portions that are not exposed at the time of manufacturing, a part of the inorganic matrix precursor flows out in the peeling step, and the amount of the inorganic medium thus becomes smaller than that in the light-emitting layers 12, 14, and 16 that are exposed portions which are exposed at the time of manufacturing. For this reason, in the deactivation layers 13, 15, and 17, the QDs are not protected and deactivated.

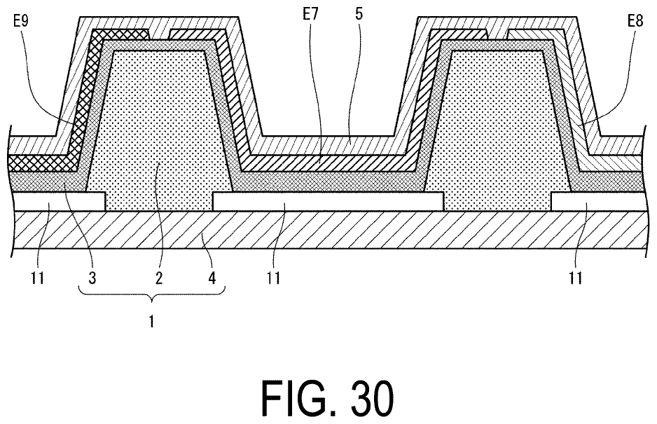

FIG. 30 is a cross-sectional view of a light-emitting element according to a comparative example. Constituent elements similar to the constituent elements described above are denoted by the same reference signs and numerals, and detailed descriptions thereof will not be repeated.

A first light-emitting layer E7, a second light-emitting layer E8, and a third light-emitting layer E9 are exposed portions that are exposed at the time of manufacturing, and as illustrated in FIG. 30, they are formed so as to extend above the banks 2, respectively. Therefore, there is a problem in that portions of the first light-emitting layer E7, the second light-emitting layer E8, and the third light-emitting layer E9 formed above the banks 2 emit light due to electro-luminescence (EL) or photoluminescence (PL), and the color purities are reduced. For example, the color purity is reduced as a result of blue light emitted due to EL of the third light-emitting layer E9, passing through the first light-emitting layer E7 formed above the bank 2, and the first light-emitting layer E7 corresponding to red light emitting light due to PL.

Thus, in the second embodiment, in order to suppress the reduction in the color purities, mask exposure is used as a form of exposure for reacting the inorganic matrix precursor, and the deactivation layers 13, 15, and 17 extending above the banks 2 are deactivated so as to suppress PL and EL.

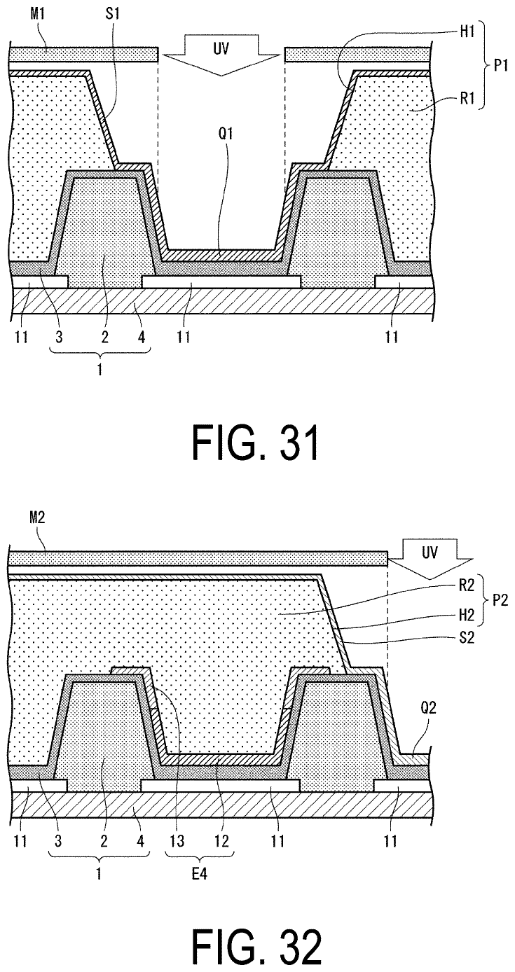

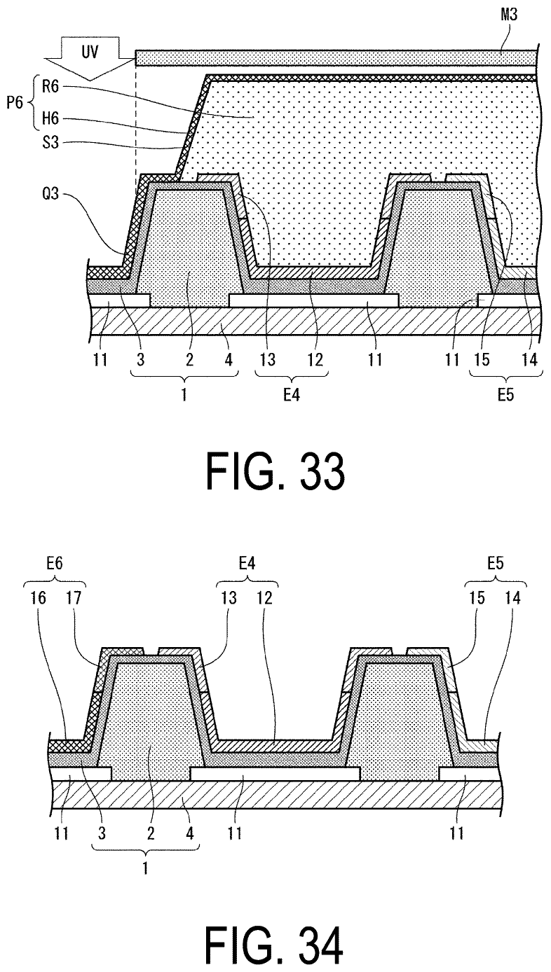

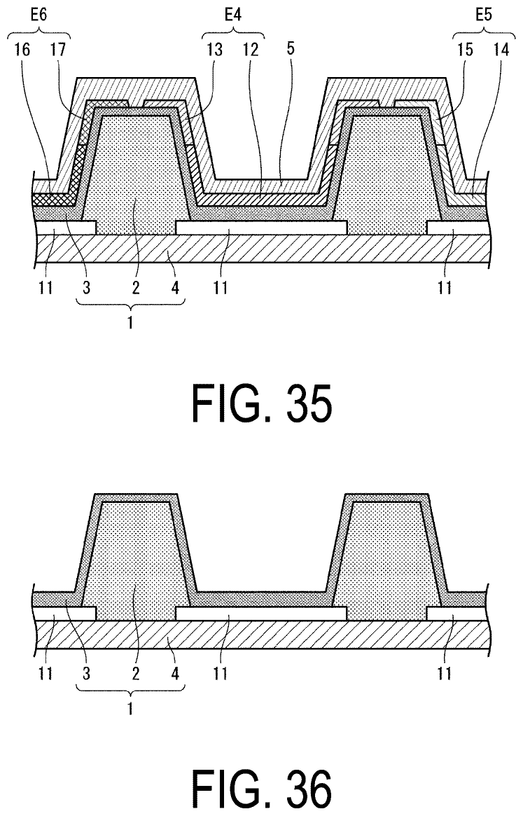

FIG. 31 is a cross-sectional view illustrating a first exposure step of a method for manufacturing a light-emitting element according to the second embodiment. FIG. 32 is a cross-sectional view illustrating a second exposure step of the method for manufacturing the light-emitting element. FIG. 33 is a cross-sectional view illustrating a third exposure step of the method for manufacturing the light-emitting element. FIG. 34 is a cross-sectional view illustrating a peeling step of the method for manufacturing the light-emitting element. FIG. 35 is a cross-sectional view illustrating a CTL forming step of the method for manufacturing the light-emitting element. Constituent elements similar to the constituent elements described above are denoted by the same reference signs and numerals, and detailed descriptions thereof will not be repeated.

After performing the lower layer forming step, the first color template forming step, and the first color application step, as illustrated in FIG. 31, by causing, using a mask M1, portions, of the coating film of the first solution S1, located above the banks 2 to be unexposed portions, and causing a part of the inorganic matrix precursor material to flow out in the peeling step, the first quantum dots included in the unexposed portions are deactivated in the peeling step or a step subsequent thereto in which application or the like is performed. The exposed portions become the first metal sulfide film Q1 including the plurality of first quantum dots.

Then, after performing the peeling step, the second color template forming step, and the second color application step, as illustrated in FIG. 32, by causing, using a mask M2, portions, of the coating film of the second solution S2, located above the banks 2 to be unexposed portions, and causing a part of the inorganic matrix precursor material to flow out in the peeling step, the second quantum dots included in the unexposed portions are deactivated. The exposed portions become the second metal sulfide film Q2 including the plurality of second quantum dots.

Subsequently, after performing the second color peeling step, the third color template forming step, and the third color application step, as illustrated in FIG. 33, by causing, using a mask M3, portions, of the coating film of the third solution S3, located above the banks 2 to be unexposed portions, and causing a part of the inorganic matrix precursor material to flow out in the peeling step, the third quantum dots included in the unexposed portions are deactivated. The exposed portions become the third metal sulfide film Q3 including the plurality of third quantum dots.

Then, as illustrated in FIG. 34, the third resist portion R6 of the third resist pattern P6 is removed so as to leave at least a part of the third metal sulfide film Q3 as the third light-emitting layer E6.

The first light-emitting layer E4 includes the light-emitting layer 12 including the plurality of quantum dots that are luminescent, and the deactivation layer 13 including the plurality of quantum dots that are deactivated. The second light-emitting layer E5 includes the light-emitting layer 14 including the plurality of quantum dots that are luminescent, and the deactivation layer 15 including the plurality of quantum dots that are deactivated. The third light-emitting layer E6 includes the light-emitting layer 16 including the plurality of quantum dots that are luminescent, and the deactivation layer 17 including the plurality of quantum dots that are deactivated.

Subsequently, as illustrated in FIG. 35, the upper function layer 5 is formed to be in contact with the first light-emitting layer E4, the second light-emitting layer E5, and the third light-emitting layer E6.

### Third Embodiment

When the inorganic QD layers are separately patterned by the lift-off method, the light-emitting layers become strong, and thus the peelability of the resist pattern is lowered. In a third embodiment, the peelability of the resist pattern is improved.

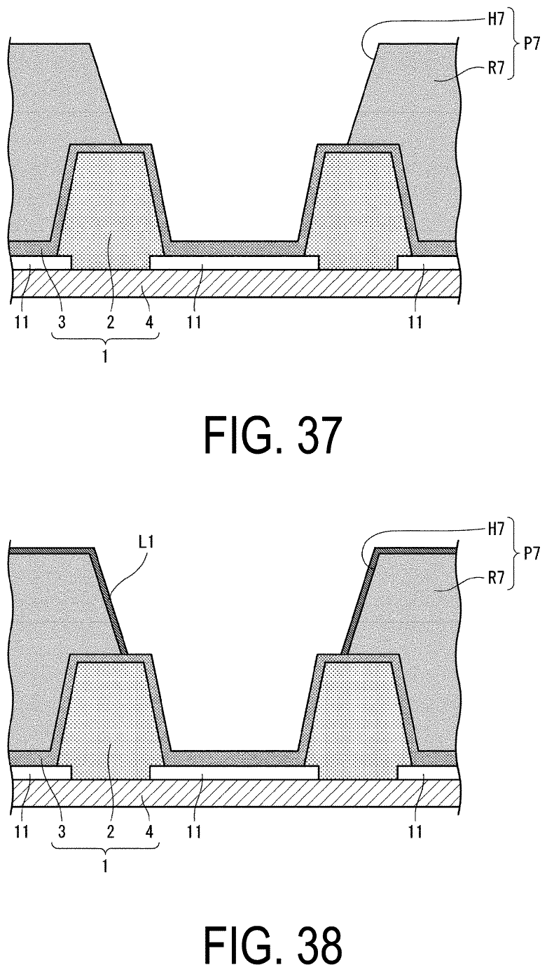

FIG. 36 is a cross-sectional view illustrating a lower layer forming step of a method for manufacturing a light-emitting element according to the third embodiment. FIG. 37 is a cross-sectional view illustrating a first color template forming step of the method for manufacturing the light-emitting element. Constituent elements similar to the constituent elements described above are denoted by the same reference signs and numerals, and detailed descriptions thereof will not be repeated.

First, as illustrated in FIG. 36, the underlayer substrate 1 is prepared that includes the substrate 4, the bank 2 formed on the substrate 4, and the lower function layer 3 that is formed so as to cover the substrate 4 and the bank 2. Note that the lower function layer 3 may be separately patterned.

Then, as illustrated in FIG. 37, a first resist pattern P7, including a first resist portion R7 made of a material having resistance to a specific solvent, and a first opening H7, is formed on the underlayer substrate 1. The specific solvent is a polar solvent or a low-polarity solvent.

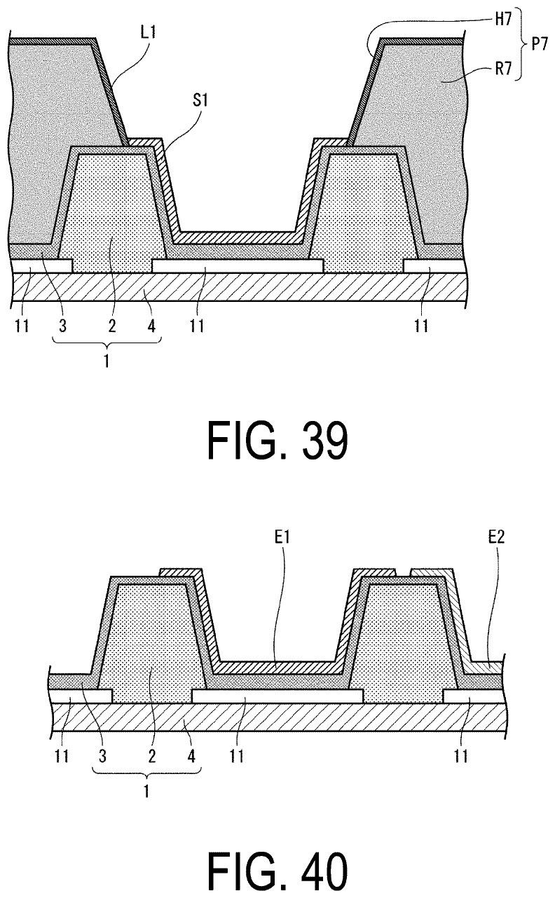

FIG. 38 is a cross-sectional view illustrating a liquid repellency imparting step according to a post application method of the method for manufacturing the light-emitting element. FIG. 39 is a cross-sectional view illustrating a first color application step according to the post application method. FIG. 40 is a cross-sectional view illustrating an exposure/peeling step according to the post application method. Constituent elements similar to the constituent elements described above are denoted by the same reference signs and numerals, and detailed descriptions thereof will not be repeated.

Subsequently, as illustrated in FIG. 38, in order to impart liquid repellency to the surface of the first resist portion R7 of the first resist pattern P7, a solution including a liquid-repellent agent to be bonded to the first resist portion R7 is applied to the surface to form a liquid-repellent portion L1 so that the liquid-repellent portion L1 covers the first resist portion R7.

Thereafter, as illustrated in FIG. 39, the first solution S1 including the plurality of first quantum dots that are luminescent, a polar solvent, and the precursor of the inorganic matrix is applied onto the lower function layer 3. The first solution S1 is not applied to the first resist portion R7 due to the liquid-repellent effect of the liquid-repellent portion L1.

Then, the exposure step or a baking step and the peeling step are performed, and the liquid repellency is also imparted to the second resist portion in the same manner, thereby forming the first light-emitting layer E1 and the second light-emitting layer E2, as illustrated in FIG. 40.

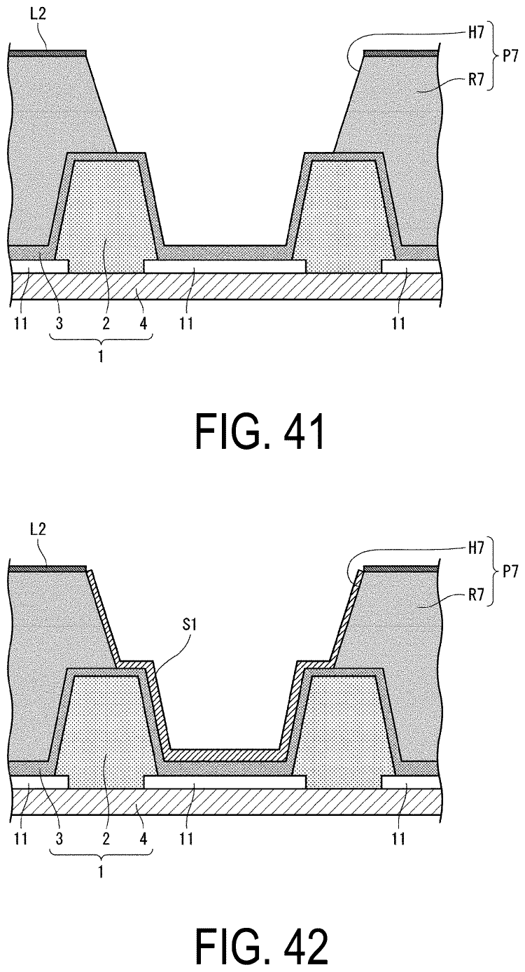

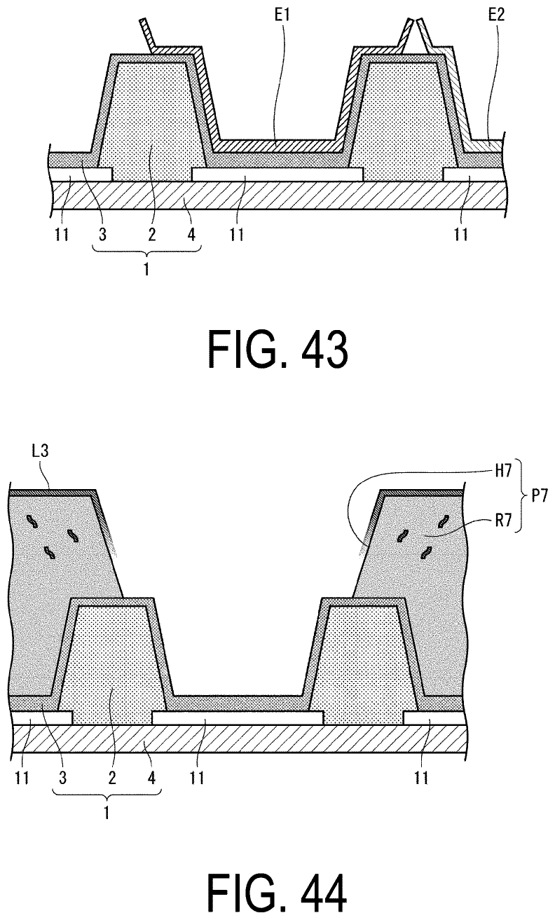

FIG. 41 is a cross-sectional view illustrating a liquid repellency imparting step according to a transfer method of the method for manufacturing the light-emitting element. FIG. 42 is a cross-sectional view illustrating a first color application step according to the transfer method. FIG. 43 is a cross-sectional view illustrating an exposure/peeling step according to the transfer method. Constituent elements similar to the constituent elements described above are denoted by the same reference signs and numerals, and detailed descriptions thereof will not be repeated.

After forming the first resist pattern P7 as illustrated in FIG. 37, in order to impart liquid repellency to the upper surface of the first resist portion R7, a liquid-repellent portion L2 is formed on the upper surface of the first resist portion R7 by the transfer method, as illustrated in FIG. 41.

Then, as illustrated in FIG. 42, the first solution S1 including the plurality of first quantum dots that are luminescent, the specific solvent, and the precursor of the inorganic matrix is applied to the lower function layer 3 and the inner walls of the first opening H7 of the first resist pattern P7. The first solution S1 is not applied to the upper surface of the first resist portion R7 due to the liquid-repellent effect of the liquid-repellent portion L2.

Subsequently, the exposure step or a baking step and the peeling step are performed, and the liquid repellency is also imparted to the second resist portion in the same manner, thereby forming the first light-emitting layer E1 and the second light-emitting layer E2, as illustrated in FIG. 43.

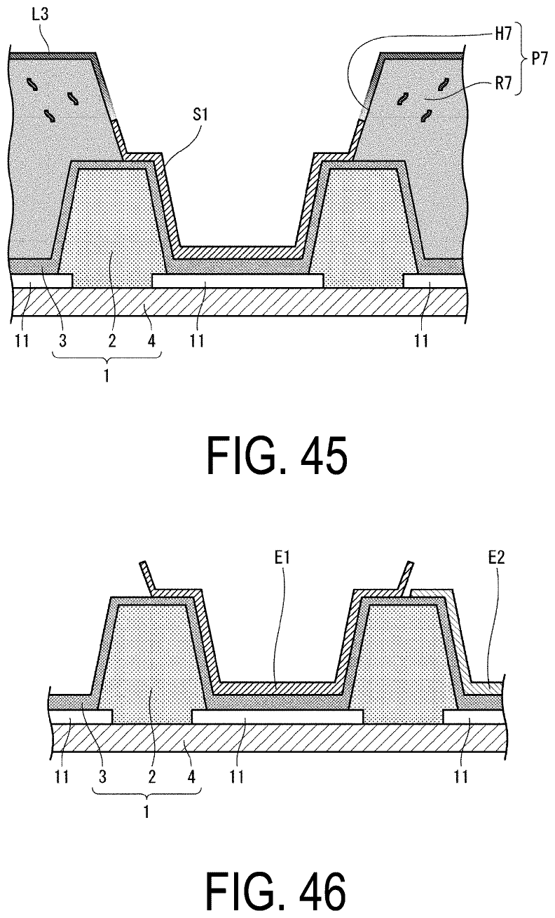

FIG. 44 is a cross-sectional view illustrating a liquid repellency imparting step according to a liquid-repellent agent mixing resist method of the method for manufacturing the light-emitting element. FIG. 45 is a cross-sectional view illustrating a first color application step according to the liquid-repellent agent mixing resist method. FIG. 46 is a cross-sectional view illustrating an exposure/peeling step according to the liquid-repellent agent mixing resist method. Constituent elements similar to the constituent elements described above are denoted by the same reference signs and numerals, and detailed descriptions thereof will not be repeated.

A liquid-repellent agent constituting a liquid-repellent portion L3 is applied simultaneously with the first resist pattern P7 in the first color template forming step illustrated in FIG. 37. Then, the liquid-repellent agent is segregated on the surface of the first resist portion R7 by exposure to the atmosphere or baking to form the liquid-repellent portion L3, as illustrated in FIG. 44.

Then, as illustrated in FIG. 45, the first solution S1 including the plurality of first quantum dots that are luminescent, the specific solvent, and the precursor of the inorganic matrix is applied onto the lower function layer 3 and onto lower portions of the inner walls of the first opening H7 of the first resist pattern P7. The first solution S1 is not applied to the upper surface of the first resist portion R7 and upper portions of the inner walls of the first opening H7 due to the liquid-repellent effect of the liquid-repellent portion L3.

Subsequently, the exposure step or a baking step and the peeling step are performed, and the liquid repellency is also imparted to the second resist portion in the same manner, thereby forming the first light-emitting layer E1 and the second light-emitting layer E2, as illustrated in FIG. 46.

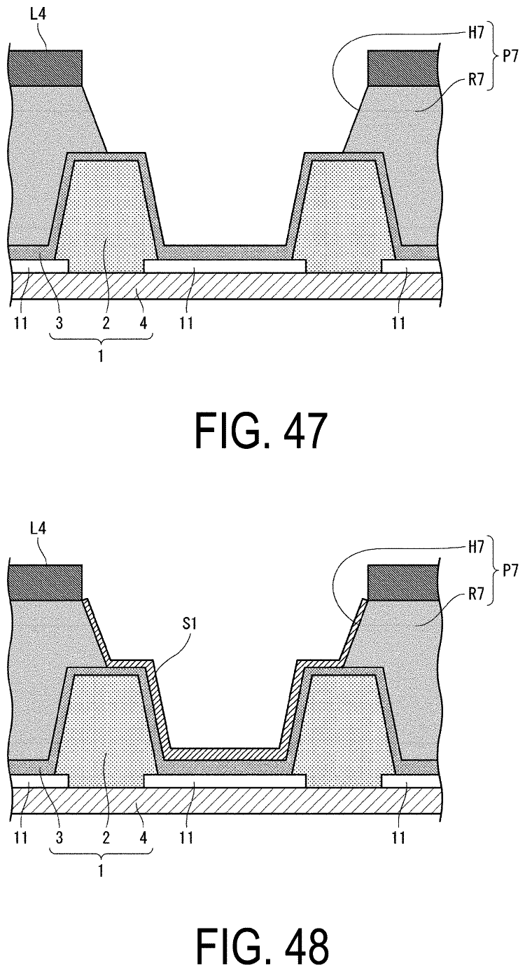

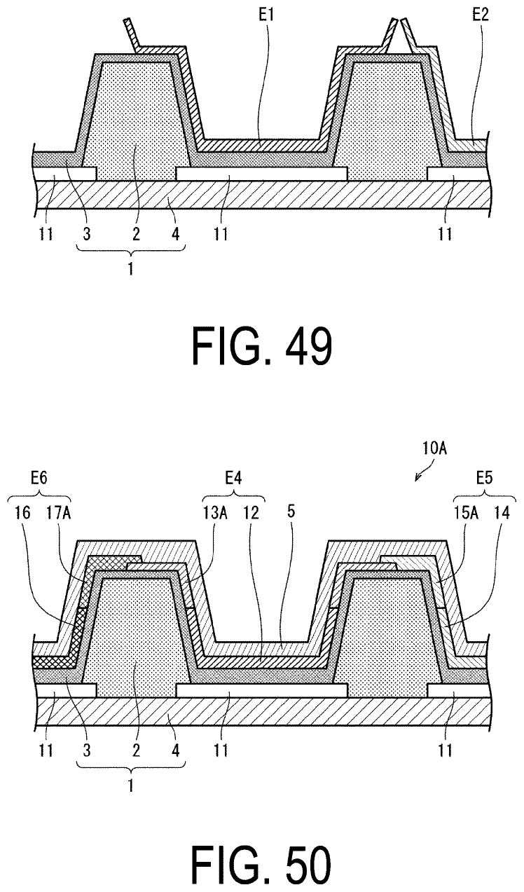

FIG. 47 is a cross-sectional view illustrating a liquid repellency imparting step according to a liquid-repellent portion layering method of the method for manufacturing the light-emitting element. FIG. 48 is a cross-sectional view illustrating a first color application step according to the liquid-repellent portion layering method. FIG. 49 is a cross-sectional view illustrating an exposure/peeling step according to the liquid-repellent portion layering method. Constituent elements similar to the constituent elements described above are denoted by the same reference signs and numerals, and detailed descriptions thereof will not be repeated.

In order to layer a resist layer having photosensitivity and liquid repellency on the first resist portion R7 and to impart liquid repellency to the upper surface of the first resist portion R7 simultaneously with the formation of the first resist pattern P7, a liquid-repellent portion L4 is formed on the upper surface of the first resist portion R7, as illustrated in FIG. 47. The liquid-repellent portion L4 has an opening corresponding to the first opening H7.

Then, as illustrated in FIG. 48, the first solution S1 including the plurality of first quantum dots that are luminescent, the specific solvent, and the precursor of the inorganic matrix is applied onto the lower function layer 3 and onto the inner walls of the first opening H7 of the first resist pattern P7. The first solution S1 is not applied to the upper surface of the first resist portion R7 due to the liquid-repellent effect of the liquid-repellent portion L4.

Subsequently, the exposure step or a baking step and the peeling step are performed, and the liquid repellency is also imparted to the second resist portion in the same manner, thereby forming the first light-emitting layer E1 and the second light-emitting layer E2, as illustrated in FIG. 49.

As described above, by imparting the liquid repellency to the upper surface of the first resist portion R7, the coating film of the first solution S1 is not formed on the upper surface of the first resist portion R7.

In this way, the coating film of the first solution S1 formed on the first resist portion R7 is reduced or eliminated. As a result, the peelability of the resist pattern can be improved.

### Fourth Embodiment

FIG. 50 is a cross-sectional view of a light-emitting element 10A according to a fourth embodiment. Constituent elements similar to the constituent elements described above are denoted by the same reference signs and numerals, and detailed descriptions thereof will not be repeated.

The light-emitting element 10A includes the lower electrodes 11, the banks 2 covering the edges of the lower electrodes 11, the light-emitting layers 12, 14, and 16 each not overlapping the bank 2 in a plan view and including the continuous film of the metal sulfide including the plurality of quantum dots, and deactivation layers 13A, 15A, and 17A each overlapping the bank 2 in a plan view, including a plurality of quantum dots, and having a concentration of the metal sulfide lower than that of the light-emitting layers 12, 14, and 16. The light-emitting layers 12, 14, and 16 are layers including the plurality of quantum dots that are luminescent, and the deactivation layers 13A, 15A, and 17A are layers including the plurality of quantum dots that are deactivated. The light-emitting layers 12, 14, and 16 are connected to the deactivation layers 13A, 15A, and 17A, respectively.

The deactivation layer 13A is layered on the deactivation layer 17A in a central portion of the upper surface of the bank 2. As a result, leakage of the current from a portion, of the lower function layer 3, in which the first light-emitting layer E4 and the third light-emitting layer E6 are not layered is suppressed.

Further, the deactivation layer 13A is layered on the deactivation layer 15A on the upper surface of the bank 2. As a result, leakage of the current from a portion, of the lower function layer 3, in which the first light-emitting layer E4 and the second light-emitting layer E5 are not layered on the upper surface of the bank 2 is suppressed.

In this way, the underlayer substrate 1 includes the bank 2 and the lower function layer 3 covering the bank 2. The first light-emitting layer E4 and the second light-emitting layer E5 overlap each other above the bank 2. Then, above the bank 2, the deactivation layer 13A (first deactivation layer) including the plurality of quantum dots (first quantum dots) that are deactivated and the deactivation layer 15A (second deactivation layer) including the plurality of quantum dots (second quantum dots) that are deactivated overlap each other.

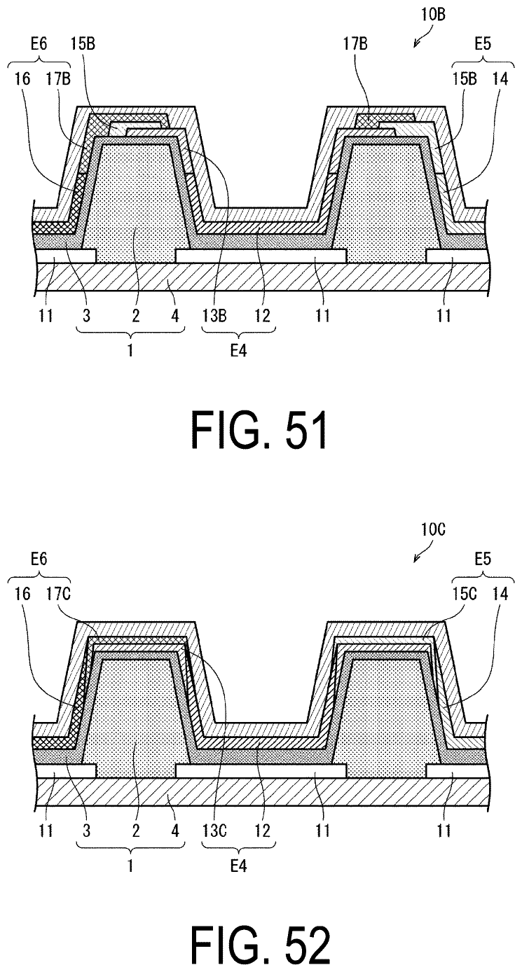

FIG. 51 is a cross-sectional view of a light-emitting element 10B according to a modified example of the fourth embodiment. Constituent elements similar to the constituent elements described above are denoted by the same reference signs and numerals, and detailed descriptions thereof will not be repeated.

The light-emitting element 10B includes the light-emitting layers 12, 14, and 16 each not overlapping the bank 2 in a plan view and including the continuous film of the metal sulfide including the plurality of quantum dots, and deactivation layers 13B, 15B, and 17B each overlapping the bank 2 in a plan view, including a plurality of quantum dots, and having a concentration of the metal sulfide lower than that of the light-emitting layers 12, 14, and 16.

The deactivation layer 13B is layered on the deactivation layer 15B and the deactivation layer 17B in the central portion of the upper surface of the bank 2. As a result, leakage of the current from the lower function layer 3 is more reliably suppressed.

FIG. 52 is a cross-sectional view of a light-emitting element 10C according to another modified example of the fourth embodiment. Constituent elements similar to the constituent elements described above are denoted by the same reference signs and numerals, and detailed descriptions thereof will not be repeated.

The light-emitting element 10C includes the light-emitting layers 12, 14, and 16 each not overlapping the bank 2 in a plan view and including the continuous film of the metal sulfide including the plurality of quantum dots, and deactivation layers 13C, 15C, and 17C each overlapping the bank 2 in a plan view, including a plurality of quantum dots, and having a concentration of the metal sulfide lower than that of the light-emitting layers 12, 14, and 16.

The deactivation layer 13C is layered on the deactivation layer 17C so as to cover the entire upper surface of the bank 2. As a result, leakage of the current is suppressed from a portion, of the lower function layer 3, that corresponds to an end portion of the upper surface of the bank 2, at which the leakage is likely to occur due to a thinner film thickness. In this way, as a result of the deactivation layers 13C and 17C being layered on each other at the portion of the bank 2 at which the leakage is likely to occur, the leakage of the current is suppressed. A part of the light-emitting layer 12 is layered on a part of the deactivation layer 13C.

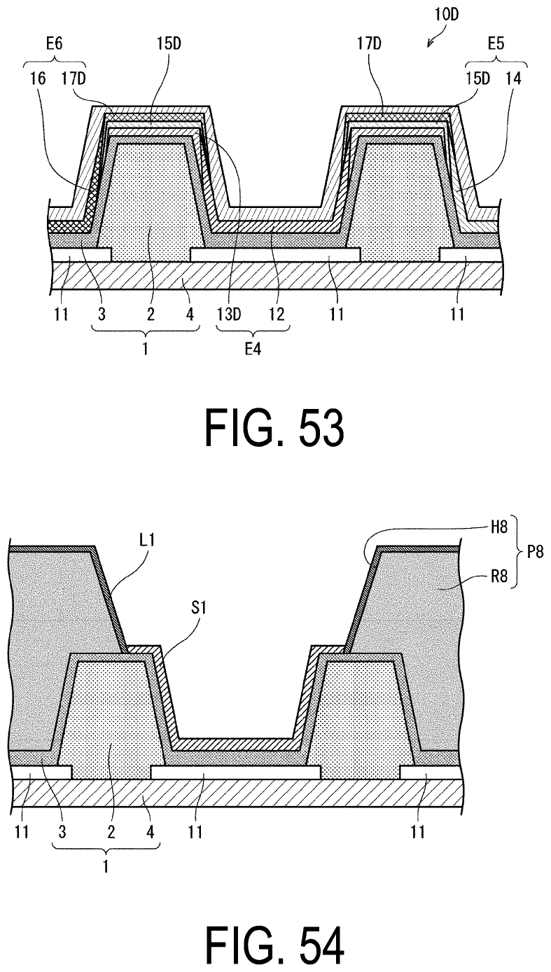

FIG. 53 is a cross-sectional view of a light-emitting element 10D of yet another modified example according to the fourth embodiment. Constituent elements similar to the constituent elements described above are denoted by the same reference signs and numerals, and detailed descriptions thereof will not be repeated.

The light-emitting element 10D includes the light-emitting layers 12, 14, and 16, and deactivation layers 13D, 15D, and 17D each having a concentration of the metal sulfide lower than that of the light-emitting layers 12, 14, and 16.

The deactivation layer 13D is layered on the deactivation layer 15D and the deactivation layer 17D so as to cover the entire upper surface of the bank 2. As a result, leakage of the current from the portion, of the lower function layer 3, corresponding to the end portion of the upper surface of the bank 2 in which the leakage is likely to occur due to a thinner film thickness is more reliably suppressed.

### Fifth Embodiment

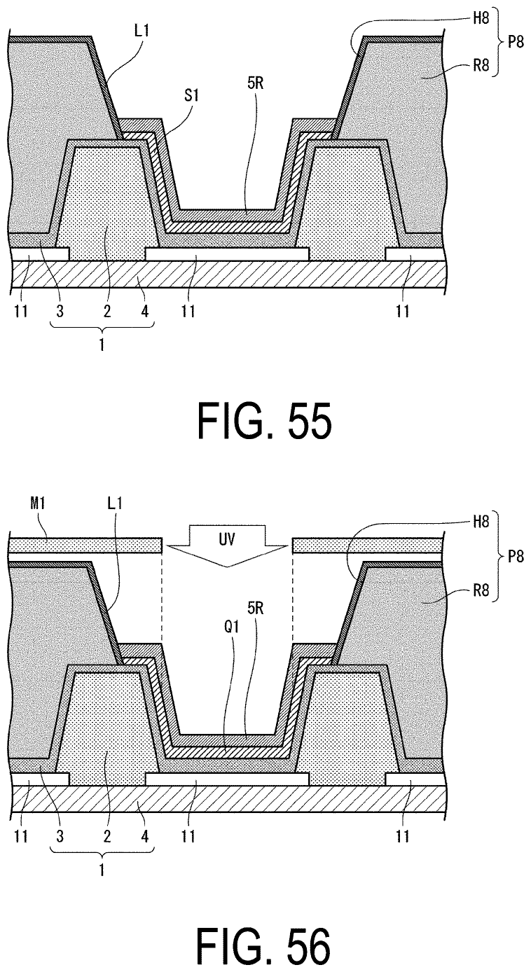

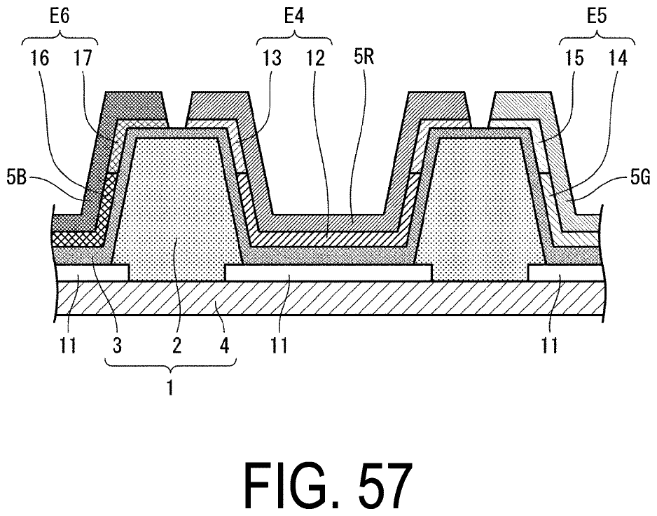

FIG. 54 is a cross-sectional view illustrating a first color application step of a method for manufacturing a light-emitting element according to a fifth embodiment. FIG. 55 is a cross-sectional view illustrating an upper layer CTL application step of the method for manufacturing the light-emitting element. FIG. 56 is a cross-sectional view illustrating an exposure step of the method for manufacturing the light-emitting element. FIG. 57 is a cross-sectional view illustrating a third color peeling step of the method for manufacturing the light-emitting element. Constituent elements similar to the constituent elements described above are denoted by the same reference signs and numerals, and detailed descriptions thereof will not be repeated.

First, as illustrated in FIG. 54, the first solution S1 including the plurality of first quantum dots that are luminescent, a polar solvent, and the precursor of the inorganic matrix is applied onto the lower function layer 3. The first solution S1 is not applied onto the first resist portion R8 due to the liquid-repellent effect of the liquid-repellent portion L1.

Then, as illustrated in FIG. 55, an upper function layer 5R is applied onto the first solution S1.

Subsequently, as illustrated in FIG. 56, by causing, using the mask M1, portions, of the coating film of the first solution S1, located above the banks 2 to be unexposed portions, the first quantum dots included in the unexposed portions are deactivated in a subsequent step. The exposed portions become the first metal sulfide film Q1 including the plurality of first quantum dots. Note that this exposure step may be performed before the application of the upper function layer 5R.

Then, by peeling the first resist pattern P8 from the lower function layer 3, the first light-emitting layer E4 including the light-emitting layer 12 corresponding to the exposed portion and the deactivation layer 13 corresponding to the unexposed portion, and the upper function layer 5R layered on the first light-emitting layer E4 are formed.

Thereafter, by performing the same steps also for the second color and the third color, as illustrated in FIG. 57, the second light-emitting layer E5 including the light-emitting layer 14 corresponding to the exposed portion and the deactivation layer 15 corresponding to the unexposed portion, and an upper function layer 5G layered on the second light-emitting layer E5 are formed, and the third light-emitting layer E6 including the light-emitting layer 16 corresponding to the exposed portion and the deactivation layer 17 corresponding to the unexposed portion and an upper function layer 5B layered on the third light-emitting layer E6 are formed.

In this way, after forming the first light-emitting layer E4, the upper function layer 5R (first upper function layer) in contact with the first light-emitting layer E4 is formed. Then, after forming the second light-emitting layer E5, the upper function layer 5G (second upper function layer) in contact with the second light-emitting layer E5 is formed.

As described above, by separately patterning each of the upper function layers 5R, 5G, and 5B, the upper function layers 5R, 5G, and 5B adapted to respective luminescent colors of the first light-emitting layer E4, the second light-emitting layer E5, and the third light-emitting layer E6 can be formed. Therefore, it is possible to improve the light-emission characteristics of the first light-emitting layer E4, the second light-emitting layer E5, and the third light-emitting layer E6.

### Sixth Embodiment

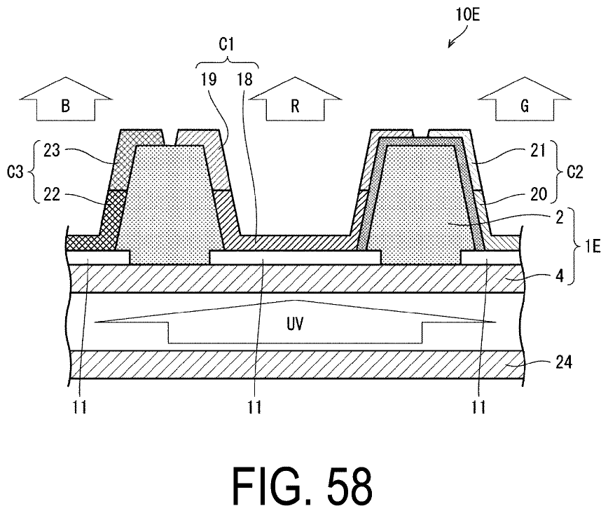

FIG. 58 is a cross-sectional view of a light-emitting element 10E according to a sixth embodiment. Constituent elements similar to the constituent elements described above are denoted by the same reference signs and numerals, and detailed descriptions thereof will not be repeated.

The light-emitting element 10E includes a light source 24 that emits ultraviolet rays, a first color conversion layer C1 that converts the ultraviolet rays emitted from the light source 24 into red light, a second color conversion layer C2 that converts the ultraviolet rays emitted from the light source 24 into green light, and a third color conversion layer C3 that converts the ultraviolet rays emitted from the light source 24 into blue light.

The first color conversion layer C1 may be configured to convert the blue light from the third color conversion layer C3 into red light. The second color conversion layer C2 may be configured to convert the blue light from the third color conversion layer C3 into green light.

The first color conversion layer Cl includes a light-emitting layer 18 not overlapping the bank 2 in a plan view and including a continuous film of metal sulfide including a plurality of quantum dots, and a deactivation layer 19 overlapping the bank 2 in a plan view, including a plurality of quantum dots, and having a concentration of the metal sulfide lower than that of the light-emitting layer 18. The second color conversion layer C2 includes a light-emitting layer 20 not overlapping the bank 2 in a plan view and including a continuous film of metal sulfide including a plurality of quantum dots, and a deactivation layer 21 overlapping the bank 2 in a plan view, including a plurality of quantum dots, and having a concentration of the metal sulfide lower than that of the light-emitting layer 20. The third color conversion layer C3 includes a light-emitting layer 22 not overlapping the bank 2 in a plan view and including a continuous film of metal sulfide including a plurality of quantum dots, and a deactivation layer 23 overlapping the bank 2 in a plan view, including a plurality of quantum dots, and having a concentration of the metal sulfide lower than that of the light-emitting layer 22.

An underlayer substrate 1E includes the substrate 4 and the bank 2 formed on the substrate 4.

In this way, the first color conversion layer C1, the second color conversion layer C2, and the third color conversion layer C3 causes photoluminescence (PL) to occur in the visible light region by receiving ultraviolet rays or blue light.

### Seventh Embodiment

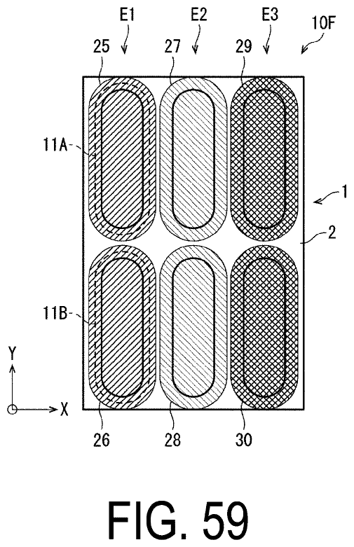

FIG. 59 is a plan view of a light-emitting element 10F according to a seventh embodiment. Constituent elements similar to the constituent elements described above are denoted by the same reference signs and numerals, and detailed descriptions thereof will not be repeated.

The light-emitting element 10F includes the first light-emitting layer E1 left as a part of the first metal sulfide film Q1 after removing the first resist portion R1, the second light-emitting layer E2 left as a part of the second metal sulfide film Q2 after removing the second resist portion R2, and the third light-emitting layer E3 left as a part of the third metal sulfide film Q3 after removing the third resist portion R3.

The first light-emitting layer E1 includes a subpixel portion 25 (first portion) and a subpixel portion 26 (second portion), which are separated from each other. The second light-emitting layer E2 includes a subpixel portion 27 (third portion) and a subpixel portion 28 (fourth portion), which are separated from each other. The third light-emitting layer E3 includes a subpixel portion 29 and a subpixel portion 30, which are separated from each other. The subpixel portion 25, the subpixel portion 27, and the subpixel portion 29 are adjacent to each other along an X direction. The subpixel portion 25 and the subpixel portion 26 are adjacent to each other along a Y direction.

In the subpixel portions 25 and 26 of the first light-emitting layer E1, the subpixel portions 27 and 28 of the second light-emitting layer E2, and the subpixel portions 29 and 30 of the third light-emitting layer E3, respective edge portions thereof are thicker than portions inside the edge portions.

The underlayer substrate 1 includes the bank 2 covering first electrodes 11A and 11B and the edges thereof. The subpixel portion 25 of the first light-emitting layer E1 overlaps the first electrode 11A in a plan view. The subpixel portion 26 of the first light-emitting layer E1 overlaps the first electrode 11B in a plan view.

In the light-emitting element 10F, the subpixel portions 25, 26, 27, 28, 29, and 30 are formed so that the respective edges thereof extend to the upper surface of the bank 2, but they are formed so as to be isolated from each other and so that the respective edges do not overlap each other.

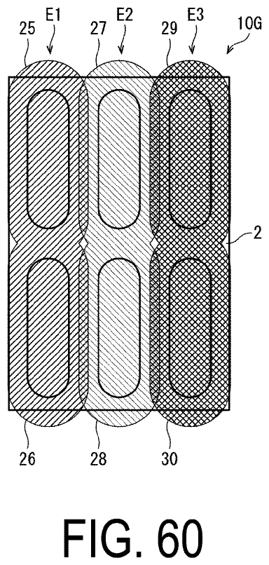

FIG. 60 is a plan view of a light-emitting element 10G according to a modified example of the seventh embodiment. Constituent elements similar to the constituent elements described above are denoted by the same reference signs and numerals, and detailed descriptions thereof will not be repeated.

The light-emitting element 10G includes the first light-emitting layer E1, the second light-emitting layer E2, and the third light-emitting layer E3. The first light-emitting layer E1 includes the subpixel portion 25 and the subpixel portion 26. The second light-emitting layer E2 includes the subpixel portion 27 and the subpixel portion 28. The third light-emitting layer E3 includes the subpixel portion 29 and the subpixel portion 30.

The subpixel portion 25 and the subpixel portion 26 may be formed to be connected to each other on the upper surface of the bank 2, the subpixel portion 27 and the subpixel portion 28 may be formed to be connected to each other on the upper surface of the bank 2, and the subpixel portion 29 and the subpixel portion 30 may be formed to be connected to each other on the upper surface of the bank 2.

The subpixel portion 25 and the subpixel portion 27 may be formed so as to overlap each other on the upper surface of the bank 2, the subpixel portion 27 and the subpixel portion 29 may be formed so as to overlap each other on the upper surface of the bank 2, the subpixel portion 26 and the subpixel portion 28 may be formed so as to overlap each other on the upper surface of the bank 2, and the subpixel portion 28 and the subpixel portion 30 may be formed so as to overlap each other on the upper surface of the bank 2.

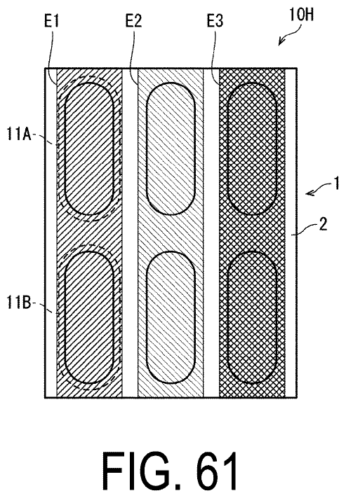

FIG. 61 is a plan view of a light-emitting element 10H according to another modified example of the seventh embodiment. Constituent elements similar to the constituent elements described above are denoted by the same reference signs and numerals, and detailed descriptions thereof will not be repeated.

The light-emitting element 10H includes the first light-emitting layer E1 left as a part of the first metal sulfide film Q1 over a plurality of subpixels of the same color after removing the first resist portion R1, the second light-emitting layer E2 left as a part of the second metal sulfide film Q2 over a plurality of subpixels of the same color after removing the second resist portion R2, and the third light-emitting layer E3 left as a part of the third metal sulfide film Q3 over a plurality of subpixels of the same color after removing the third resist portion R3.

The underlayer substrate 1 includes the first electrode 11A, a second electrode 11B, and the bank 2 covering the edges of the first electrode 11A and the second electrode 11B. The first light-emitting layer E1 overlaps the first electrode 11A and the second electrode 11B in a plan view.

The first light-emitting layer E1, the second light-emitting layer E2, and the third light-emitting layer E3 are formed so that the respective edges thereof extend to the upper surface of the bank 2, but they are formed so as to be isolated from each other and so that the respective edges do not overlap each other.

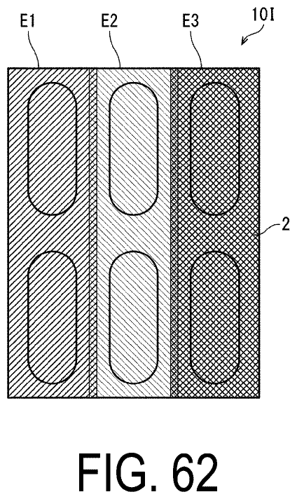

FIG. 62 is a plan view of a light-emitting element 10I according to yet another modified example. Constituent elements similar to the constituent elements described above are denoted by the same reference signs and numerals, and detailed descriptions thereof will not be repeated.

The light-emitting element 10I includes the first light-emitting layer E1, the second light-emitting layer E2, and the third light-emitting layer E3. The first light-emitting layer E1 and the second light-emitting layer E2 may be formed to overlap each other on the upper surface of the bank 2. The second light-emitting layer E2 and the third light-emitting layer E3 may be formed to overlap each other on the upper surface of the bank 2.

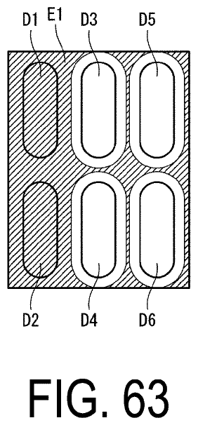

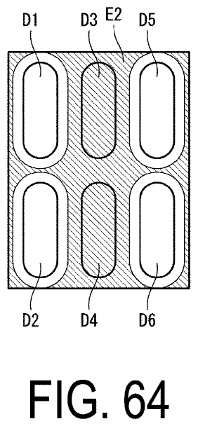

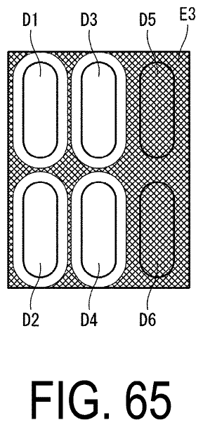

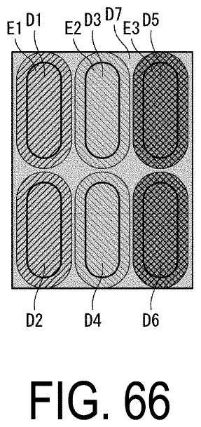

FIG. 63 is a plan view illustrating a first color forming step of a method for manufacturing a light-emitting element according to the seventh embodiment. FIG. 64 is a plan view illustrating a second color forming step of the method for manufacturing the light-emitting element. FIG. 65 is a plan view illustrating a third color forming step of the method for manufacturing the light-emitting element. FIG. 66 is a plan view illustrating a light-emitting element manufactured by the method for manufacturing the light-emitting element. Constituent elements similar to the constituent elements described above are denoted by the same reference signs and numerals, and detailed descriptions thereof will not be repeated.

First, as illustrated in FIG. 63, the first light-emitting layer E1 is formed so as to include subpixel regions D1 and D2 corresponding to the first color and not to include subpixel regions D3 and D4 corresponding to the second color and subpixel regions D5 and D6 corresponding to the third color. A region in which the first light-emitting layer E1 is not formed includes a region corresponding to the subpixel region D3, a region corresponding to the subpixel region D4, a region corresponding to the subpixel region D5, and a region corresponding to the subpixel region D6. These four regions are not continuous and formed so as to be isolated from each other.

Then, as illustrated in FIG. 64, the second light-emitting layer E2 is formed so as to include the subpixel regions D3 and D4 corresponding to the second color and not to include the subpixel regions D1 and D2 corresponding to the first color and the subpixel regions D5 and D6 corresponding to the third color. A region in which the second light-emitting layer E2 is not formed includes a region corresponding to the subpixel region D1, a region corresponding to the subpixel region D2, the region corresponding to the subpixel region D5, and the region corresponding to the subpixel region D6. These four regions are not continuous and formed so as to be isolated from each other.

Subsequently, as illustrated in FIG. 65, the third light-emitting layer E3 is formed so as to include the subpixel regions D5 and D6 corresponding to the third color and not to include the subpixel regions D1 and D2 corresponding to the first color and the subpixel regions D3 and D4 corresponding to the second color. A region in which the third light-emitting layer E3 is not formed includes the region corresponding to the subpixel region D1, the region corresponding to the subpixel region D2, the region corresponding to the subpixel region D3, and the region corresponding to the subpixel region D4. These four regions are not continuous and formed so as to be isolated from each other.

Then, as illustrated in FIG. 66, only the first light-emitting layer E1 is applied to the subpixel regions D1 and D2, and the second light-emitting layer E2 and the third light-emitting layer E3 are not applied thereto. Then, only the second light-emitting layer E2 is applied to the subpixel regions D3 and D4, and the first light-emitting layer E1 and the third light-emitting layer E3 are not applied thereto. Further, only the third light-emitting layer E3 is applied to the subpixel regions D5 and D6, and the first light-emitting layer E1 and the second light-emitting layer E2 are not applied thereto.

Then, the first light-emitting layer E1, the second light-emitting layer E2, and the third light-emitting layer E3 are layered on and applied to a layered region D7 other than the subpixel regions D1 to D6.

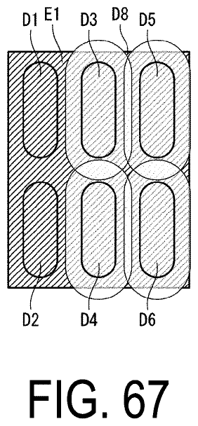

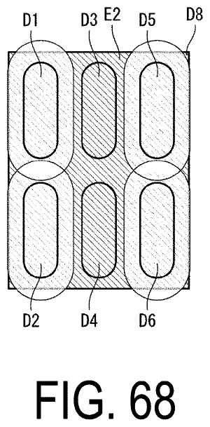

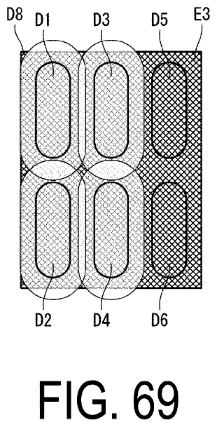

FIG. 67 is a plan view illustrating a first color forming step of another method for manufacturing a light-emitting element according to the seventh embodiment. FIG. 68 is a plan view illustrating a second color forming step of the other method for manufacturing the light-emitting element. FIG. 69 is a plan view illustrating a third color forming step of the other method for manufacturing the light-emitting element. Constituent elements similar to the constituent elements described above are denoted by the same reference signs and numerals, and detailed descriptions thereof will not be repeated.

First, as illustrated in FIG. 67, the first light-emitting layer E1 is formed so as to include the subpixel regions D1 and D2 corresponding to the first color and not to include the subpixel regions D3 and D4 corresponding to the second color and the subpixel regions D5 and D6 corresponding to the third color. The region in which the first light-emitting layer E1 is not formed includes the region corresponding to the subpixel region D3, the region corresponding to the subpixel region D4, the region corresponding to the subpixel region D5, and the region corresponding to the subpixel region D6, and, as illustrated in FIG. 67, these four regions are continuously formed.

Then, as illustrated in FIG. 68, the second light-emitting layer E2 is formed so as to include the subpixel regions D3 and D4 corresponding to the second color and not to include the subpixel regions D1 and D2 corresponding to the first color and the subpixel regions D5 and D6 corresponding to the third color. A region in which the second light-emitting layer E2 is not formed includes a region corresponding to the subpixel region D1, a region corresponding to the subpixel region D2, the region corresponding to the subpixel region D5, and the region corresponding to the subpixel region D6. As illustrated in FIG. 68, the region of the subpixel region D1 and the region of the subpixel region D2 are continuously formed. The region of the subpixel region D5 and the region of the subpixel region D6 are continuously formed.

Subsequently, as illustrated in FIG. 69, the third light-emitting layer E3 is formed so as to include the subpixel regions D5 and D6 corresponding to the third color and not to include the subpixel regions D1 and D2 corresponding to the first color and the subpixel regions D3 and D4 corresponding to the second color. A region in which the third light-emitting layer E3 is not formed includes the region corresponding to the subpixel region D1, the region corresponding to the subpixel region D2, the region corresponding to the subpixel region D3, and the region corresponding to the subpixel region D4. As illustrated in FIG. 69, these four regions are continuously formed.

Then, the first light-emitting layer E1, the second light-emitting layer E2, and the third light-emitting layer E3 are layered on and applied to a layered region D8 other than the subpixel regions D1 to D6.

The layered region D7 of the light-emitting element manufactured by the steps illustrated in FIGS. 63 to 65 is wider than the layered region D8 of the light-emitting element manufactured by the steps illustrated in FIGS. 67 to 69. In addition, the layered region D7 is formed continuously, whereas the layered region D8 is formed non-continuously. For this reason, in the light-emitting element including the layered region D7, peeling of the first light-emitting layer E1, the second light-emitting layer E2, and the third light-emitting layer E3 is less likely to occur than in the light-emitting element including the layered region D8.

In addition, in the light-emitting element including the layered region D7, since the first to third light-emitting layers E1 to E3 are layered between the subpixels, the resistance between the subpixels is increased. For this reason, the light-emitting element including the layered region D7 can suppress the leakage from between the subpixels more than the light-emitting element including the layered region D8.

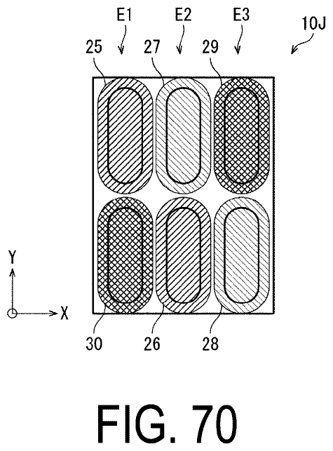

FIG. 70 is a plan view of a light-emitting element 10J according to yet another modified example of the seventh embodiment. Constituent elements similar to the constituent elements described above are denoted by the same reference signs and numerals, and detailed descriptions thereof will not be repeated.

The light-emitting element 10J includes the first light-emitting layer E1 left as a part of the first metal sulfide film Q1 after removing the first resist portion R1, the second light-emitting layer E2 left as a part of the second metal sulfide film Q2 after removing the second resist portion R2, and the third light-emitting layer E3 left as a part of the third metal sulfide film Q3 after removing the third resist portion R3.

The first light-emitting layer E1 includes a subpixel portion 25 (first portion) and a subpixel portion 26 (second portion), which are separated from each other. The second light-emitting layer E2 includes a subpixel portion 27 (third portion) and a subpixel portion 28 (fourth portion), which are separated from each other. The third light-emitting layer E3 includes a subpixel portion 29 and a subpixel portion 30, which are separated from each other. The subpixel portion 25, the subpixel portion 27, and the subpixel portion 29 are adjacent to each other along an X direction. The subpixel portion 25 and the subpixel portion 26 are adjacent to each other along a direction oblique to the X direction.

A display device according to the present embodiment includes the light-emitting element according to any one of the first to seventh embodiments.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A method for manufacturing a light-emitting element, the method comprising:
preparing an underlayer substrate;
forming a first resist pattern on the underlayer substrate, the first resist pattern including a first resist portion and a first opening, the first resist portion being made of a material having resistance to a specific solvent;
applying a first solution onto the first resist pattern, the first solution including a plurality of first quantum dots, the specific solvent, and a precursor of an inorganic medium, and the plurality of first quantum dots being luminescent;
removing the first resist portion to leave at least a portion of a first inorganic medium layer as a first light-emitting layer, the first inorganic medium layer being formed by the application of the first solution; and
exposing a coating film of the first solution, subsequent to the application of the first solution and in advance of the removal of the first resist portion, to cause an exposed portion to become the first inorganic medium layer including the plurality of first quantum dots.

2-4. (canceled)

5. The method for manufacturing the light-emitting element according to claim 1,
wherein the specific solvent is a low-polarity solvent.

6. The method for manufacturing the light-emitting element according to claim 1,
wherein the underlayer substrate includes a bank, and
a portion of the first light-emitting layer is located above the bank.

7. The method for manufacturing the light-emitting element according to claim 1,
wherein the underlayer substrate includes a bank, and
by causing a portion, of the coating film of the first solution, located above the bank to become an unexposed portion, the first quantum dots included in the unexposed portion are deactivated.

8. (canceled)

9. The method for manufacturing the light-emitting element according to claim 1, the method comprising:
subsequent to forming the first light-emitting layer,
forming a second resist pattern including a second resist portion and a second opening, the second resist portion being made of a material having resistance to the specific solvent, and the second opening at least partially overlapping a region in which the first light-emitting layer is not formed;
applying a second solution onto the second resist pattern, the second solution including a plurality of second quantum dots, the specific solvent, and a precursor of an inorganic medium, and the plurality of second quantum dots being luminescent;
exposing a coating film of the second solution to cause an exposed portion to become a second inorganic medium layer including the plurality of second quantum dots; and
removing the second resist portion to leave at least a portion of the second inorganic medium layer as a second light-emitting layer,
wherein the underlayer substrate includes a bank and a lower function layer covering the bank, and
the first light-emitting layer and the second light-emitting layer overlap each other above the bank.

10. (canceled)

11. The method for manufacturing the light-emitting element according to claim 1, the method comprising:
subsequent to forming the first light-emitting layer,
forming a second resist pattern including a second resist portion and a second opening, the second resist portion being made of a material having resistance to the specific solvent, and the second opening at least partially overlapping a region in which the first light-emitting layer is not formed;
applying a second solution onto the second resist pattern, the second solution including a plurality of second quantum dots, the specific solvent, and a precursor of an inorganic medium, and the plurality of second quantum dots being luminescent;
exposing a coating film of the second solution to cause an exposed portion to become a second inorganic medium layer including the plurality of second quantum dots; and
removing the second resist portion to leave at least a portion of the second inorganic medium layer as a second light-emitting layer,
wherein the underlayer substrate includes a bank and a lower function layer covering the bank, and
a first deactivation layer including the first quantum dots that are deactivated and a second deactivation layer including the second quantum dots that are deactivated overlap each other above the bank.

12-13. (canceled)

14. The method for manufacturing the light-emitting element according to claim 1,
wherein an edge portion of the first light-emitting layer is thicker than a portion of the first light-emitting layer inside the edge portion,
the underlayer substrate includes a first electrode and a second electrode, and a bank covering edges of the first electrode and the second electrode, and
the first light-emitting layer overlaps the first electrode and the second electrode in a plan view.

15-16. (canceled)

17. The method for manufacturing the light-emitting element according to claim 1, the method comprising:
subsequent to forming the first light-emitting layer,
forming a second resist pattern including a second resist portion and a second opening, the second resist portion being made of a material having resistance to the specific solvent, and the second opening at least partially overlapping a region in which the first light-emitting layer is not formed;
applying a second solution onto the second resist pattern, the second solution including a plurality of second quantum dots, the specific solvent, and a precursor of an inorganic medium, and the plurality of second quantum dots being luminescent;
exposing a coating film of the second solution to cause an exposed portion to become a second inorganic medium layer including the plurality of second quantum dots; and
removing the second resist portion to leave at least a portion of the second inorganic medium layer as a second light-emitting layer,
wherein the first quantum dot and the second quantum dot emit different colors,
the first light-emitting layer includes a first portion and a second portion that are separated from each other,
the second light-emitting layer includes a third portion and a fourth portion that are separated from each other,
the first portion and the third portion are adjacent to each other in a first direction, and
the first portion and the second portion are adjacent to each other in a direction orthogonal to the first direction or in a direction oblique to the first direction.

18-19. (canceled)

20. The method for manufacturing the light-emitting element according to claim 1,
wherein the inorganic medium is metal sulfide.

21. The method for manufacturing the light-emitting element according to claim 20,
wherein the metal sulfide is zinc sulfide.

22. The method for manufacturing the light-emitting element according to claim 1,
wherein the inorganic medium is zinc sulfide, and
the precursor of the zinc sulfide is zinc dithiocarboxylate.

23. The method for manufacturing the light-emitting element according to claim 1,
wherein the first resist portion includes a PVA-PVP grafted copolymer.

24. The method for manufacturing the light-emitting element according to claim 5,
wherein the low-polarity solvent includes toluene.

25. (canceled)

26. The method for manufacturing the light-emitting element according to claim 1,
wherein the first resist portion is removed by a stripper to which a surfactant is added.

27. The method for manufacturing the light-emitting element according to claim 1,
wherein the first resist portion includes an OH group.

28-30. (canceled)

31. A light-emitting element comprising:
a lower electrode;
a bank covering an edge of the lower electrode;
a first inorganic medium layer not overlapping the bank in a plan view and including a continuous film of an inorganic medium including a plurality of quantum dots; and
a second inorganic medium layer overlapping the bank in a plan view, including a plurality of quantum dots, and having a concentration of the inorganic medium lower than a concentration of the first inorganic medium layer.

32. The light-emitting element according to claim 31,
wherein the first inorganic medium layer is a light-emitting layer including the plurality of quantum dots that are luminescent, and
the second inorganic medium layer is a deactivation layer including a plurality of quantum dots that are deactivated.

33. The light-emitting element according to claim 32,
wherein the light-emitting layer and the deactivation layer are connected to each other.

34. The light-emitting element according to claim 33,
wherein the light-emitting layer and a portion of the deactivation layer are layered.

35. A display device comprising the light-emitting element according to claim 31.
